(19) United States
(12) Patent Application Publication
(10) Pub. No.: US 2026/0231752 A1
(43) Pub. Date: Aug. 6, 2026

(54) INTEGRATED CIRCUIT (IC) DEVICE AND METHOD

(71) Applicant: TAIWAN SEMICONDUCTOR MANUFACTURING COMPANY, LTD., Hsinchu (TW)

(72) Inventors: Yi-Jui CHANG, Hsinchu (TW); Po-Wen CHENG, Hsinchu (TW); Wei-Ren CHEN, Hsinchu (TW); Wei-Ling CHANG, Hsinchu (TW); Johnny Chiahao LI, Hsinchu (TW)

(21) Appl. No.: 19/220,705

(22) Filed: May 28, 2025

Related U.S. Application Data
(60) Provisional application No. 63/754,891, filed on Feb. 6, 2025.

(51) Int. Cl. H01L 23/528; H01L 21/3213; H01L 23/522; H10D 89/10

(52) U.S. Cl. CPC H10W 20/427; H10D 89/10; H10P 50/71; H10W 20/42

(57) ABSTRACT

An IC device includes a first transistor, and a second transistor. The first transistor includes a first terminal configured to receive a first power supply voltage, a second terminal, and a gate terminal. The gate terminal is configured to receive a second power supply voltage different from the first power supply voltage, or a first voltage corresponding to the first power supply voltage, or a second voltage corresponding to the second power supply voltage. The second transistor includes two terminals electrically coupled to the second terminal of the first transistor.

### RELATED APPLICATION(S)

This application claims the benefit of U.S. Provisional Application No. 63/754,891, filed Feb. 6, 2025, which is herein incorporated by reference in its entirety.

### BACKGROUND

An integrated circuit (“IC”) device includes one or more semiconductor devices represented in an IC layout diagram (also referred to as “IC design layout diagram,” “layout diagram,” “IC layout,” or “layout”). A layout diagram is hierarchical and includes modules which carry out higher-level functions in accordance with the semiconductor device's design specifications. The modules are often built from a combination of cells, each of which represents one or more semiconductor structures configured to perform a specific function. Cells having pre-designed layout diagrams, sometimes known as standard cells, are stored in standard cell libraries (hereinafter “libraries” or “cell libraries” for simplicity) and accessible by various tools, such as electronic design automation (EDA) tools, to generate, optimize and verify designs for ICs.

Engineering change order (ECO) cells are examples of standard cells in cell libraries. An ECO cell is a cell pre-designed without a specific function, but is programmable to provide an intended function. For example, to design an IC device, the pre-designed layouts of one or more functional cells are read out from a standard cell library and placed into an initial IC layout. The IC layout also includes one or more ECO cells which are not yet connected or routed to the functional cells. When the IC layout is to be revised, one or more of the already placed ECO cells are programmed to provide an intended function and routed to the functional cells. The programming of ECO cells involves modifications in one or more layers of the IC layout and/or masks for manufacturing the IC device.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A is a block diagram of an IC device, in accordance with some embodiments.

FIG. 1B is a schematic cross-sectional view of a circuit region of an IC device, in accordance with some embodiments.

FIG. 1C is a schematic view of a layout of a circuit region of an IC device, in accordance with some embodiments.

FIG. 1D includes electric diagrams of various dummy devices undesirable or forbidden in one or more ECO cells, in accordance with some embodiments.

FIGS. 2A, 2B, 2C, 2D include electric diagrams and voltage characteristics of various devices in one or more ECO cells, in accordance with some embodiments.

FIGS. 3A, 3B, 3C include electric diagrams of various example circuits in one or more ECO cells, in accordance with some embodiments.

FIG. 4A is a schematic view of a layout of an ECO cell, in accordance with some embodiments.

FIG. 4B is a schematic view of a layout of an ECO cell, in accordance with some embodiments.

FIG. 4C includes electric diagrams of various devices in the ECO cell described with respect to FIG. 4B, in accordance with some embodiments.

FIG. 4D is a schematic view of a layout of an ECO cell, in accordance with some embodiments.

FIGS. 5A-5C are flowcharts of various methods, in accordance with some embodiments.

FIG. 6 is a block diagram of an electronic design automation (EDA) system in accordance with some embodiments.

FIG. 7 is a block diagram of an IC device manufacturing system, and an IC manufacturing flow associated therewith, in accordance with some embodiments.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed. Source/drain(s) may refer to a source or a drain, individually or collectively dependent upon the context.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some embodiments, an ECO cell comprises a device configured to receive a power supply voltage, and provide a soft power supply voltage. In at least one embodiment, a soft power supply voltage is either a constant voltage near the power supply voltage, or a voltage hovering near the power supply voltage. The ECO cell further comprises one or more dummy devices each having two or more terminals electrically coupled to receive the soft power supply voltage. As a result, in at least one embodiment, the ECO cell includes no floating source/drains. This is an improvement over other approaches in which an ECO cell include one or more undesirable floating source/drains.

In some embodiments, an ECO cell as described herein is advantageous in situations where a cell height is reduced due to IC miniaturization and a number of tracks for conductors or conductive patterns of a metal layer over the ECO cell is limited. An example embodiment includes four tracks over an ECO cell. In other approaches, such a limited number of tracks makes it impossible to remove undesirable floating source/drains, without increasing the size of an ECO cell, or adding more ECO cells, or utilizing routing resources of one or more higher metal layers. ECO cells in accordance with some embodiments make it possible to eliminate undesirable floating source/drains, without increasing the size or number of ECO cells, thereby achieving advantages including, but not limited to, chip area improvement, increased flexibility and/or utility in ECO cell designs, or the like.

In some embodiments, no gate in an ECO cell has a direct electrical connection to a positive power rail configured to carry a positive power supply voltage. In at least one embodiment, a direct electrical connection is an electrical connection that does not pass through a switching or controllable device. In one or more embodiments, a direct electrical connection of an element to a positive power rail permits a voltage on the positive power rail to be supplied to the element independently and/or irrespectively of other elements and/or circuits. In some embodiments, because no gate in an ECO cell has a direct electrical connection to a positive power rail, it is possible to avoid or reduce electrostatic discharge (ESD) risks potentially harmful to devices in the ECO cell. Further features in accordance with various embodiments and corresponding advantages are also described herein.

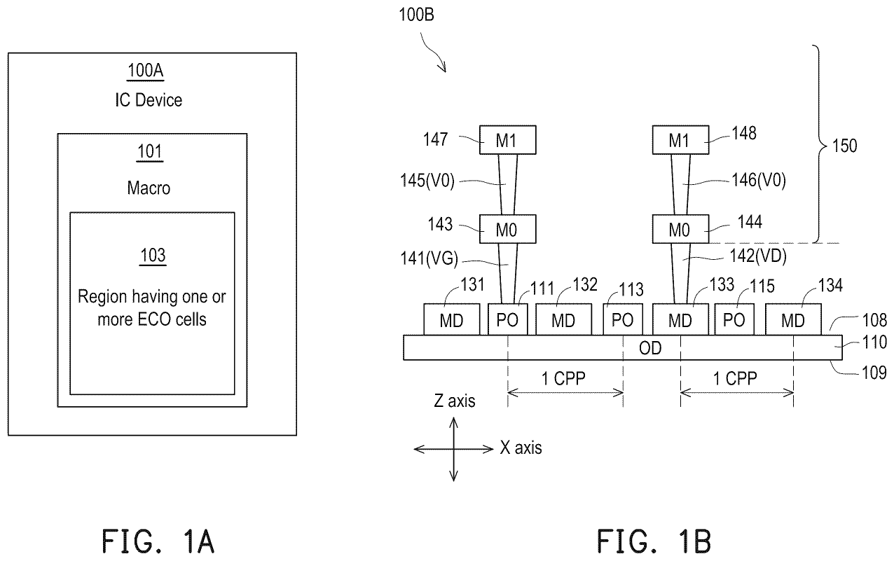

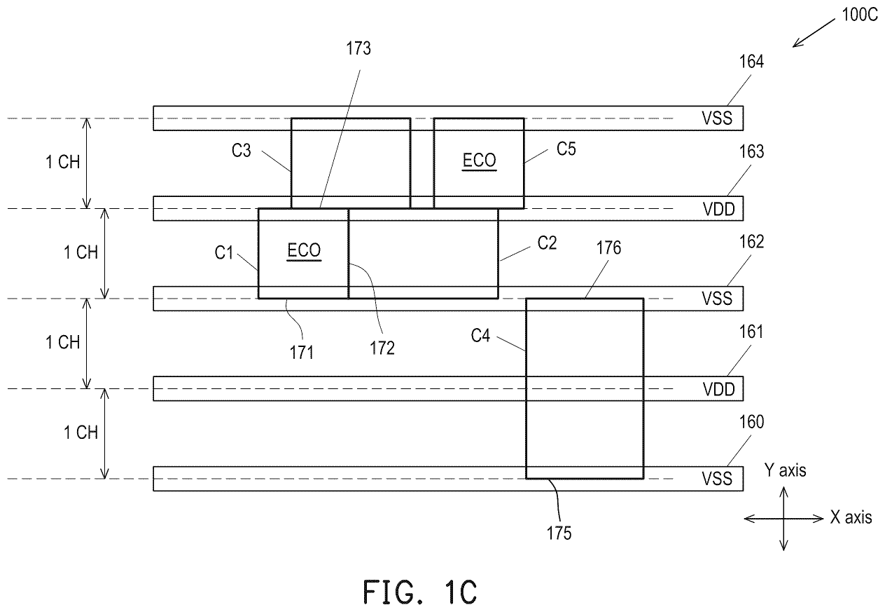

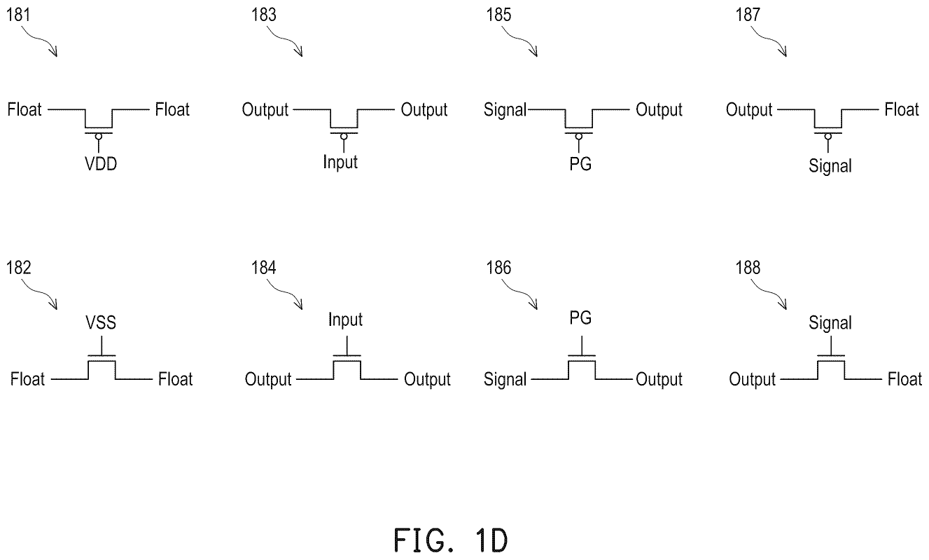

FIG. 1A is a block diagram of an IC device 100A, in accordance with some embodiments.

In FIG. 1A, the IC device 100A comprises, among other things, a macro 101. In some embodiments, the macro 101 comprises one or more of a memory, a power grid, a cell or cells, an inverter, a latch, a buffer and/or any other type of circuit arrangement that may be represented digitally in a cell library. In some embodiments, the macro 101 is understood in the context of an analogy to the architectural hierarchy of modular programming in which subroutines/procedures are called by a main program (or by other subroutines) to carry out a given computational function. In this context, the IC device 100A uses the macro 101 to perform one or more given functions. Accordingly, in this context and in terms of architectural hierarchy, the IC device 100A is analogous to the main program and the macro 101 is analogous to subroutines/procedures. In some embodiments, the macro 101 is a soft macro. In some embodiments, the macro 101 is a hard macro. In some embodiments, the macro 101 is a soft macro which is described digitally in register-transfer level (RTL) code. In some embodiments, synthesis, placement and routing have yet to have been performed on the macro 101 such that the soft macro can be synthesized, placed and routed for a variety of process nodes. In some embodiments, the macro 101 is a hard macro which is described digitally in a binary file format (e.g., Graphic Database System II (GDSII) stream format), where the binary file format represents planar geometric shapes, text labels, other information and the like of one or more layout-diagrams of the macro 101 in hierarchical form. In some embodiments, synthesis, placement and routing have been performed on the macro 101 such that the hard macro is specific to a particular process node.

The macro 101 includes a circuit region 103, which comprises one or more ECO cells, as described herein. In some embodiments, the circuit region 103 comprises a substrate having circuitry formed thereon, in a front-end-of-line (FEOL) fabrication. Furthermore, above and/or below the substrate, the circuit region 103 comprises various metal layers that are stacked over and/or under insulating layers in a back-end-of-line (BEOL) fabrication. The BEOL provides routing for circuitry of the IC device 100A, including the macro 101 and the circuit region 103.

FIG. 1B is a schematic cross-sectional view of a circuit region of an IC device 100B, in accordance with some embodiments. In some embodiments, the IC device 100B corresponds to the IC device 100A, and/or the circuit region in FIG. 1B corresponds to the circuit region 103 and/or a circuit region that comprises one or more cells placed and routed as described herein.

As shown in FIG. 1B, the IC device 100B comprises a substrate 110 over which circuit elements and structures corresponding to one or more cells described herein are formed. The substrate 110 has a first side 108 and a second side 109 opposite one another along a thickness direction of the substrate 110, i.e., along a Z axis. In at least one embodiment, the first side 108 is referred to as “upper side” or “front side” or “device side,” whereas the second side 109 is referred to as “lower side” or “back side.” The substrate 110 comprises, in at least one embodiment, silicon, silicon germanium (SiGe), gallium arsenic, or other suitable semiconductor or dielectric materials.

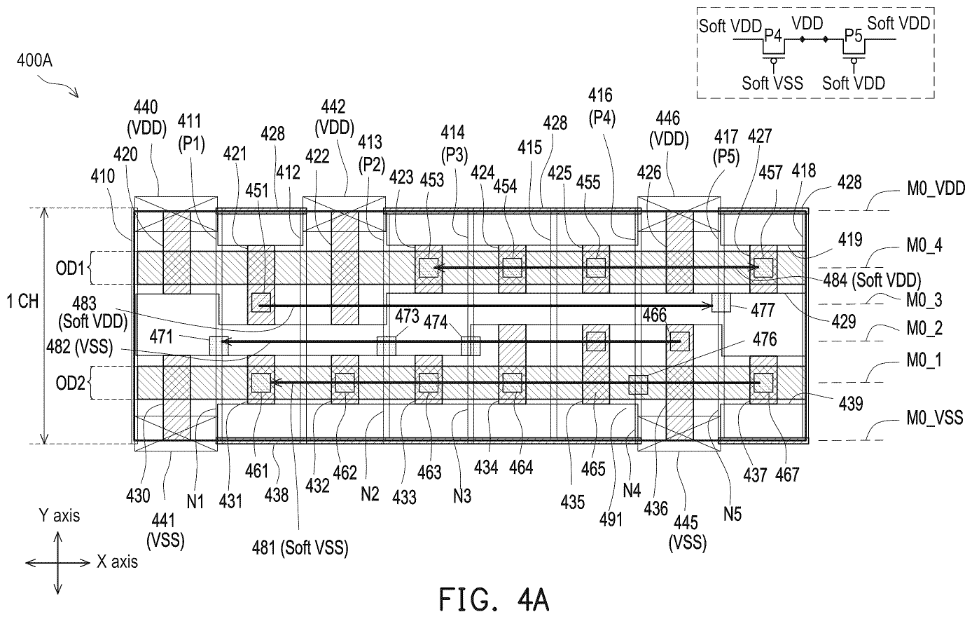

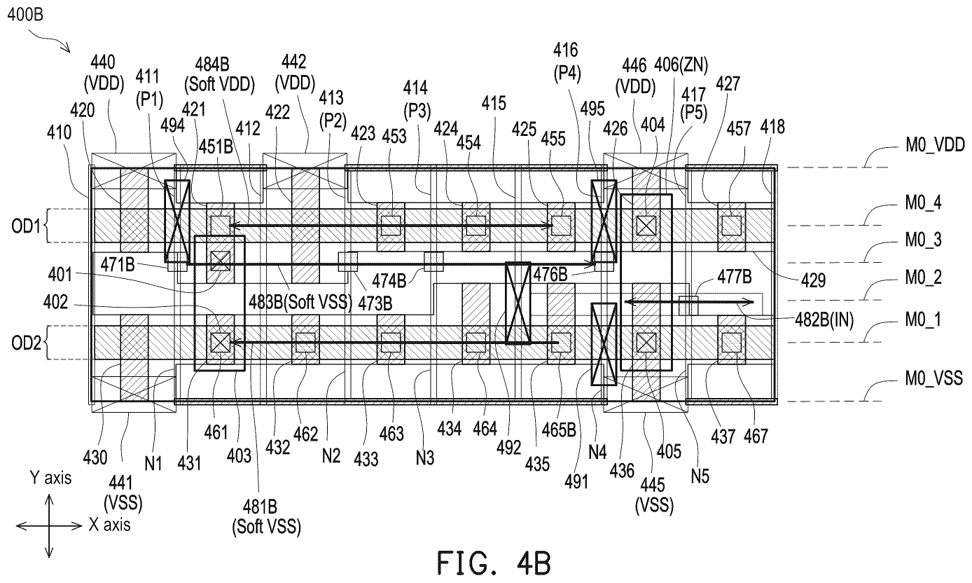

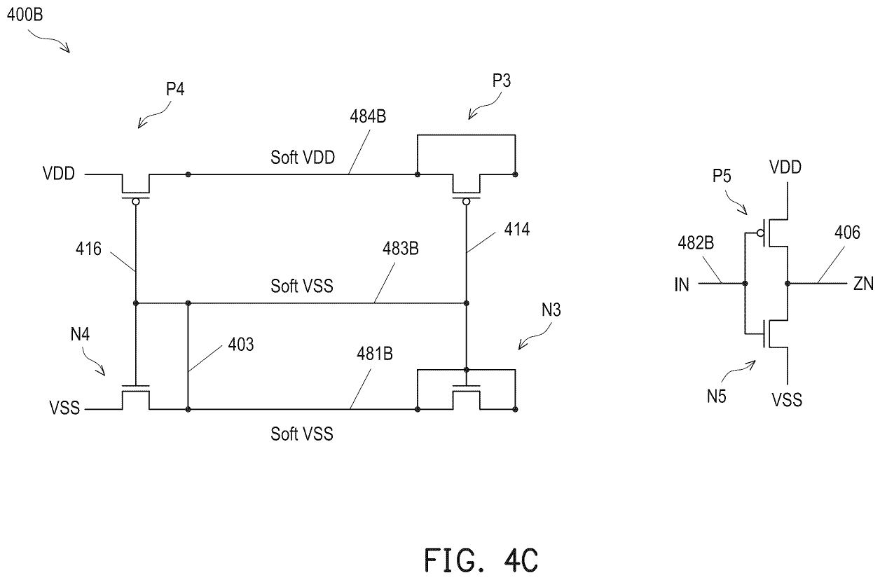

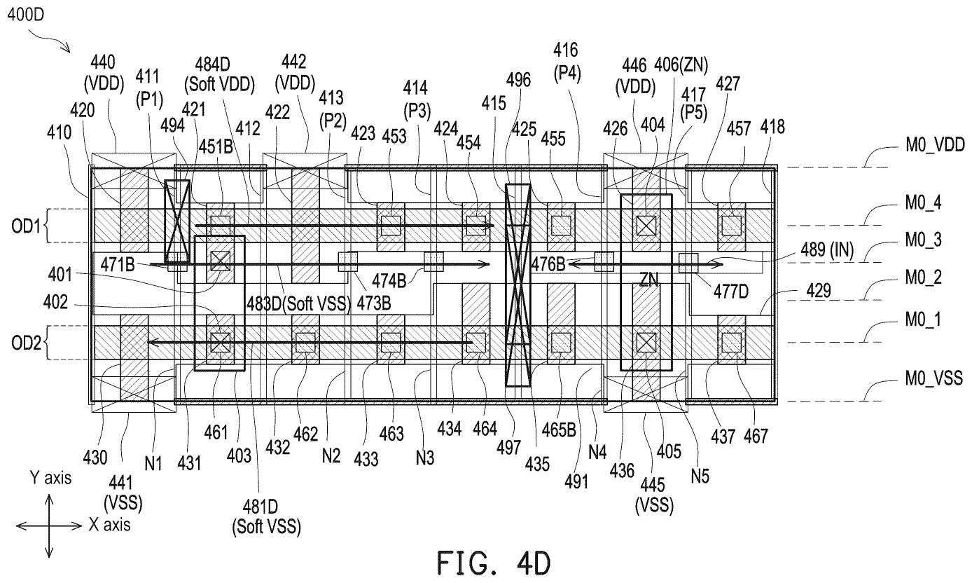

The IC device 100B further comprises N-type and P-type dopants added to the substrate 110 to correspondingly form N-type active regions and P-type active regions. The N-type active regions and P-type active regions are collectively referred to as active regions, and are schematically designated in the drawings with the label “OD.” In some embodiments, isolation structures are formed between adjacent active regions. For simplicity, isolation structures are omitted from FIG. 1B. In at least one embodiment, the active region(s) in FIG. 1B correspond(s) to one or more of active regions described with respect to FIGS. 4A, 4B, 4D.

The IC device 100B further comprises various gate structures over the active regions. In some embodiments, a gate structure comprises a gate, and a gate dielectric between the gate and the underlying active region. For simplicity, gate dielectrics are omitted from FIG. 1B. Example materials of gate dielectrics include HfO2, ZrO2, or the like. Gates are schematically illustrated in the drawings with the label “PO.” Gates 111, 113, 115 are shown in FIG. 1B, for example. In some embodiments, gates of the IC device 100B include conductive gates and dielectric gates. Example materials of conductive gates include conductive materials, such as, polysilicon, metal, or the like. Example materials of dielectric gates include dielectric materials Conductive gates and the underlying active regions configure transistors or devices. Examples of devices include, but are not limited to, metal oxide semiconductor field effect transistors (MOSFETs), complementary metal oxide semiconductor (CMOS) transistors, P-channel metal-oxide semiconductor (PMOS) transistors, N-channel metal-oxide semiconductor (NMOS) transistors, bipolar junction transistors (BJTs), high voltage transistors, high frequency transistors, P-channel and/or N-channel field effect transistors (PFETs/NFETs), FinFETs, planar MOS transistors with raised source/drains, nanosheet FETs, nanowire FETs, or the like.

The IC device 100B further comprises contact structures over and in electrical contact with corresponding source/drains of transistors in the active regions, for electrically coupling the source/drains of the transistors to other circuit elements. Contact structures are sometimes referred to as metal-to-device structures, and are schematically illustrated in the drawings with the label “MD.” For example, MD contact structures 131-134 are illustrated in FIG. 1B. An example conductive material of MD contact structures includes metal. The gates 111, 113, 115 and the MD contact structures 131-134 are alternatingly arranged along an X axis. A pitch, i.e., a center-to-center distance along the X axis, between immediately adjacent MD contact structures (e.g., the MD contact structures 133, 134) is the same as a pitch CPP between immediately adjacent gates (e.g., the gates 111, 113). Two gates (including conductive and/or dielectric gates) are considered immediately adjacent along the X axis where there is no other gate (including a conductive gate or a dielectric gate) therebetween. Two MD contact structures are considered immediately adjacent along the X axis where there is no other MD contact structure therebetween.

The IC device 100B further comprises via structures or vias over and in electrical contact with the corresponding gates or MD contact structures. A via over and in electrical contact with an MD contact structure is sometimes referred to as via-to-device (VD), and is schematically illustrated in the drawings with the label “VD.” A via over and in electrical contact with a gate is sometimes referred to as via-to-gate (VG), and is schematically illustrated in the drawings with the label “VG.” In the example configuration in FIG. 1B, an example VG via 141 is over and in electrical contact with the gate 111, and an example VD via 142 is over and in electrical contact with the MD contact structure 133. An example material of the VD and VG vias includes metal.

The IC device 100B further comprises, on the front side 108, an interconnect structure or redistribution structure 150 which is over the VD and VG vias, and comprises a plurality of metal layers and a plurality of via layers arranged alternatingly in the thickness direction of the substrate 110, i.e., along the Z axis. The lowermost metal layer immediately over and in electrical contact with the VD and VG vias is a metal-zero (M0) layer. In other words, the M0 layer is the lowermost metal layer over, or the closest metal layer to, the active regions on the front side of the substrate. A next metal layer immediately over the M0 layer is a metal-one (M1) layer, or the like. Conductors or conductive patterns in the M0 layer are referred to herein as M0 conductors or M0 conductive patterns, conductors or conductive patterns in the M1 layer are referred to herein as M1 conductors or M1 conductive patterns, or the like. A via layer Vn is arranged between and electrically couple the Mn layer and the Mn+1 layer, where n is an integer form zero and up. For example, a via-zero (V0) layer is the lowermost via layer which is arranged between and electrically couple the M0 layer and the M1 layer. Other via layers are V1, V2, or the like. Metal layers, such as M0, M1, or the like, and via layers, such as V0, V1, or the like, on the front side of the substrate are referred to herein as front side metal layers and front side via layers. The redistribution structure 150 further comprises various interlayer dielectric (ILD) layers (not shown or numbered) in which the metal layers and via layers are embedded. The metal layers and via layers of the redistribution structure 150 are configured to electrically couple various elements or circuits of the IC device 100B with each other, and/or with external circuitry. For simplicity, metal layers and via layers above the M1 layer are omitted in FIG. 1B. In the example configuration in FIG. 1B, the M0 layer comprises M0 conductors 143, 144 correspondingly over and in electrical contact with the VG via 141 and VD via 142. The V0 layer comprises V0 vias 145, 146 correspondingly over and in electrical contact with the M0 conductors 143, 144. The M1 layer comprises M1 conductors 147, 148 correspondingly over and in electrical contact with the V0 vias 145, 146. In at least one embodiment, the M0 conductors provide internal routing for a cell, and the V0 vias, M1 conductors and/or one or more higher via layers and metal layers provide an electrical connection to the cell from other cells of the IC device 100B. Other configurations are within the scopes of various embodiments. In some embodiments, the IC device 100B further comprises, on the back side 109, a further redistribution structure (not shown) sometimes referred to as a back side redistribution structure, e.g., for configuring a power delivery network for the IC device 100B. In some embodiments, such a back side redistribution structure is omitted.

FIG. 1C is a schematic view of a layout of a circuit region of an IC device 100C, in accordance with some embodiments. In some embodiments, the IC device 100C corresponds to one or more of the IC devices 100A, 100B, and/or the circuit region in FIG. 1C corresponds to the circuit region 103 in FIG. 1A and/or the circuit region in FIG. 1B. In some embodiments, the layout 100C, as well as other layouts described herein with respect to various embodiments, are generated by an EDA system, such as an automated placement and routing (APR) system, and/or stored in a non-transitory, computer-readable storage medium. Descriptions herein with respect to the layout 100C, as well as other layouts in accordance with various embodiments, are applicable to IC devices including circuit regions corresponding to the described layouts.

The layout 100C comprises a plurality of power rails 160-164 elongated along a first axis (i.e., X axis) and spaced, by a center-to-center interval CH (cell height), from each other along a second axis (Y axis) transverse to the first axis. In at least one embodiment, the Y axis is perpendicular to the X axis. The power rails 160-164 are configured to provide a first power supply voltage, and a second power supply voltage different from the first power supply voltage. For example, the first power supply voltage is one of VSS and VDD, and the second power supply voltage is the other of VSS and VDD. Power rails configured to provide VSS are sometimes referred to herein as VSS power rails, and power rails configured to provide VDD are sometimes referred to herein as VDD power rails. A VDD power rail is an example of a positive power rail. A VDD power rail is an example of one of a first power rail and a second power rail, and a VSS power rail is an example of the other of the first power rail and the second power rail. VDD power rails and VSS power rails are alternatingly arranged along the Y axis. In the example configuration in FIG. 1B, the power rails 160, 162, 164 are VSS power rails which are alternatingly arranged with VDD power rails comprising the power rails 161, 163. In some embodiments, the power rails 160-164 are elongated M0 conductive patterns. In at least one embodiment, one or more of the power rails 160-164 are elongated conductive patterns of a back side redistribution structure.

The layout 100C further comprises a plurality of cells, such as cells C1-C5, placed therein in a placement operation performed by an EDA tool, such as an APR system, with respect to the power rails 160-164. The cells C1-C5 are schematically represented in FIG. 1C by their corresponding boundaries. One or more cells are placed in the placement operation with their boundaries in abutment with the boundaries of one or more further cells. For example, in the X axis, the cell C1 is placed in abutment with the cell C2 along a common edge 172. In the Y axis, the cell C1 is placed in abutment with the cell C3 along a common edge 173. Cells are not always placed (or placeable) in abutment. For example, the cell C4 is placed to be spaced from the cell C2 along the X axis. The described placement operation is an example. Other placement operations are within the scopes of various embodiments.

A cell is placed over one or more of the power rails 160-164 to receive VDD and/or VSS from the power rails. In some embodiments, a cell is placed with the corresponding boundary over and coinciding with center lines of two power rails. A cell height of the cell along the Y axis corresponds to a center-to-center distance between the two power rails. For example, in FIG. 1C, the boundary of the cell C1 has edges 171, 173 over and coinciding correspondingly with the center lines of the power rails 162, 163. As a result, the cell C1 has a cell height of 1 CH (single cell height) being the center-to-center distance between the power rails 162, 163. Similarly, the boundary of the cell C2 has edges (not numbered) over and coinciding correspondingly with the center lines of the power rails 162, 163. Various devices and/or circuits in the cells C1, C2 are configured to receive VSS from the power rail 162, and VDD from the power rail 163. For another example, the boundary of the cell C4 has edges 175, 176 over and coinciding correspondingly with the center lines of the power rails 160, 162. As a result, the cell C4 has a cell height of 2 CH (double cell height) being the center-to-center distance between the power rails 160, 162. The cell C4 is further over the power rail 161. Various devices and/or circuits in the cell C4 is configured to receive VSS from the power rails 160, 162, and VDD from the power rail 161. The described cells with single cell height or double cell height are examples. Other cells with greater cell heights, e.g., 3 CH, 4 CH, or the like, are within the scopes of various embodiments.

The plurality of cells in the layout 100C comprises functional cells and one or more ECO cells. For example, the cells C2, C3, C4 are functional cells, and the cells C1, C5 are ECO cells.

Functional cells correspond to various functional circuits of the IC device. The functional circuits are configured to perform one or more functions of the IC device. In some embodiments, the functional circuits comprises one or more active devices, logic circuits, or the like. Examples of logic circuits include, but are not limited to, AND, OR, NAND, NOR, XOR, INV, AND-OR-Invert (AOI), OR-AND-Invert (OAI), MUX, Flip-flop, BUFF, Latch, delay, clock, memory, or the like. Example memory cells include, but are not limited to, a static random access memory (SRAM), a dynamic RAM (DRAM), a resistive RAM (RRAIVI), a magnetoresistive RAM (MRAM), a read only memory (ROM), or the like. Examples of active devices or active elements include, but are not limited to, transistors, diodes, or the like.

ECO cells include ECO base cells and ECO programmed cells. An ECO programmed cell is an ECO base cell which has been programmed. Similar to a functional cell, an ECO base cell is pre-configured with a specific internal arrangement of various components, such as active regions, gates, MD contact structures. In some embodiments, an ECO base cell is not configured to provide a specific function. In such embodiments, contrast to functional cells which operate or are operational, an ECO base cell which has not yet been programmed does not operate or is not operational. During the IC device designing stage, when a need arises, e.g., to improve timing or meet one or more timing requirements, one or more placed ECO base cells are programmed to operate and provide one or more functions similar to those of functional cells. Examples of functions provided by programmed ECO cells include, but are not limited to, inverter, NAND, NOR, XOR, D-latch, decoupling capacitor (DCAP), and-or-invert (AOI), or-and-invert (OAI), multiplexer, flip-flop, or the like.

In some embodiments, an ECO base cell is programmed into a programmed ECO cell by altering one or more connections within the ECO base cell, such as, VD vias, VG vias, M0 conductive patterns, V0 vias, or the like. In at least one embodiment, programming an ECO base cell comprises replacing the ECO base cell placed in the layout with a pre-defined programmed ECO cell stored in and read from a cell library. The pre-defined programmed ECO cell has configurations of active regions, gates and MD contact structures identical to configurations of active regions, gates and MD contact structures in the ECO base cell, thereby minimizing changes or modifications to the layout. The programmed ECO cell differs from the ECO base cell in one or more connections within the ECO cell, such as, VD vias, VG vias, M0 conductive patterns, V0 vias, or the like. In some embodiments, placed ECO base cells are not routed, in a routing operation after the placement operation, because the ECO base cells are not operational. When one or more ECO base cells undergo programming, which converts the one or more ECO base cells into one or more programmed ECO cells which are operational, the programmed ECO cells are routed, in a re-routing operation, to be operatively connected to one or more functional cells in the layout. In a non-limiting example, the cells C1, C5 initially placed in the layout 100C are ECO base cells. Later, the cell C1 is programmed to become, or is replaced with, a programmed ECO cell, whereas the cell C5 remains an ECO base cell. The cell C1 is routed in a re-routing operation to be operatively coupled to one or more functional cells in the layout 100C, whereas the cell C5 remains unrouted, i.e., not operatively coupled to functional cells in the layout 100C.

In some embodiments, instead of one or more ECO base cells, one or more programmed ECO cells are initially placed in a layout in a placement operation. In at least one embodiment, such initially placed programmed ECO cells are not configured to provide a logic function, but are rather configured to provide a function not related to logic operations of the IC device. For example, programmed ECO cells initially placed in the layout are configured to provide the decoupling function, and include one or more decoupling capacitors. Such programmed ECO cells are sometimes referred to as DCAP cells or filler cells. In other words, ECO base cells in one or more embodiments are DCAP cells. In some embodiments, initially placed DCAP cells are electrically coupled to corresponding VSS power rails and/or VDD power rails, but are not otherwise operatively coupled or routed to functional cells in the layout. When a need arises, at least one initially placed DCAP cell is programmed to become, or replaced with, a further programed ECO cell configured to provide a function other than the decoupling function. The further programed ECO cell is then routed, in a re-routing operation, to be operatively connected to one or more functional cells in the layout. In a non-limiting example, the cells C1, C5 initially placed in the layout 100C are DCAP cells. Later, the cell C1 is programmed to become, or is replaced with, a further programmed ECO cell, e.g., an inverter cell, whereas the cell C5 remains a DCAP cell. The cell C1 (now an inverter cell) is routed in a re-routing operation to be operatively coupled to one or more functional cells in the layout 100C, whereas the cell C5 remains unrouted, i.e., not operatively coupled to functional cells in the layout 100C. In at least one embodiment, one or more ECO base cells and one or more DCAP cells are initially placed in a layout, for later replacement with one or more programed ECO cells. Other arrangements are within the scopes of various embodiments.

FIG. 1D includes electric diagrams of various dummy devices 181-188 undesirable or forbidden in one or more ECO cells, in accordance with some embodiments.

In some embodiments, a dummy device is a device or transistor that is not configured to perform any function. A dummy device that poses a potential risk, such as, an ESD risk, or the like, is considered undesirable or forbidden, and is not included in ECO cells in accordance with some embodiments. Three types of forbidden dummy devices exist: floating source/drain dummy devices, inverter dummy devices, and output dummy devices.

The dummy devices 181, 182 are examples of floating source/drain dummy devices. The dummy device 181 is a P-type transistor, e.g., a PMOS transistor, having a gate electrically coupled to VDD, and two floating source/drains. The dummy device 182 is an N-type transistor, e.g., an NMOS transistor, having a gate electrically coupled to VSS, and two floating source/drains. In some situations, the electrical connection of the gate of the dummy device 181 to VDD poses an ESD risk. A reason is that VDD is supplied to the gate of the dummy device 181 by a VDD power rail as described herein. A VDD power rail is generally a large, and long metal net or pattern capable of accumulating a large amount of charge during fabrication of IC devices. Specifically, in manufacturing operations subsequent to formation of transistors or devices of an IC device, various dielectric and metal layers are deposited and patterned to obtain conductive vias and/or patterns electrically coupled to gates of the transistors. Deposition and/or patterning operations often include plasma operations, such as plasma etching operations, plasma deposition operations, or the like. In plasma operations, it is possible that a sufficiently large amount of electrical charge is accumulated on a conductor (e.g., a VDD power rail as in the situation of the dummy device 181) coupled to a gate, and causes breakdown of the underlying gate dielectric and related damage. This issue is referred to as “plasma induced gate oxide damage” (PID), or “antenna effect,” which potentially causes yield and/or reliability concerns during a semiconductor manufacturing process. In some embodiments, an ECO cell, be it an ECO base cell or a programmed ECO cell, contains no gate with a direct electrical connection to a positive power rail, therefore, avoiding the described antenna effect violation risk.

The dummy devices 183, 184 are examples of inverter dummy devices. The dummy device 183 is a P-type transistor, e.g., a PMOS transistor, having a gate electrically coupled to an input net, and each of two source/drains electrically coupled to an output net. The dummy device 184 is an N-type transistor, e.g., an NMOS transistor, having a gate electrically coupled to an input net, and each of two source/drains electrically coupled to an output net.

The dummy devices 185-188 are examples of output dummy devices. The dummy device 185 is a P-type transistor, e.g., a PMOS transistor, having a gate electrically coupled to a power rail, a source/drain electrically coupled to a signal net, and another source/drain coupled to an output net. The dummy device 184 is an N-type transistor, e.g., an NMOS transistor, having a gate electrically coupled to a power rail, a source/drain electrically coupled to a signal net, and another source/drain coupled to an output net. The power rail coupled to the gate of the dummy device 185 or the dummy device 186 is a VDD power rail or a VSS power rail, and is schematically labeled as “PG” (power ground). The dummy device 187 is a P-type transistor, e.g., a PMOS transistor, having a gate electrically coupled to a signal net, a source/drain electrically coupled to an output net, and another source/drain floating. The dummy device 188 is an N-type transistor, e.g., an NMOS transistor, having a gate electrically coupled to a signal net, a source/drain electrically coupled to an output net, and another source/drain floating.

ECO cells described herein with respect to various embodiments do not include, or are free of, the dummy devices 181-188. For example, the cells C1, C5 described with respect to FIG. 1C, as initially placed or after replacement or programming, are free of the dummy devices 181-188.

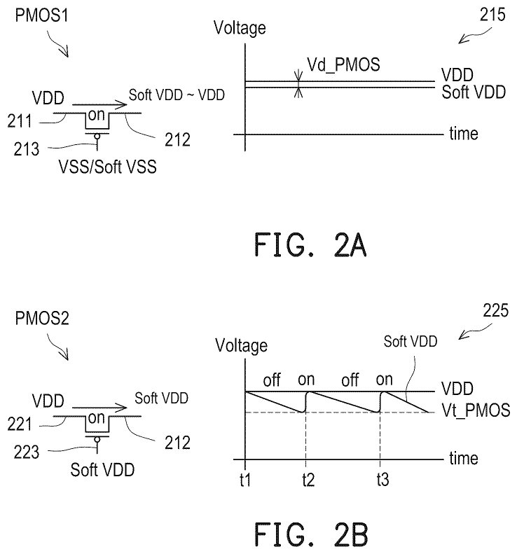

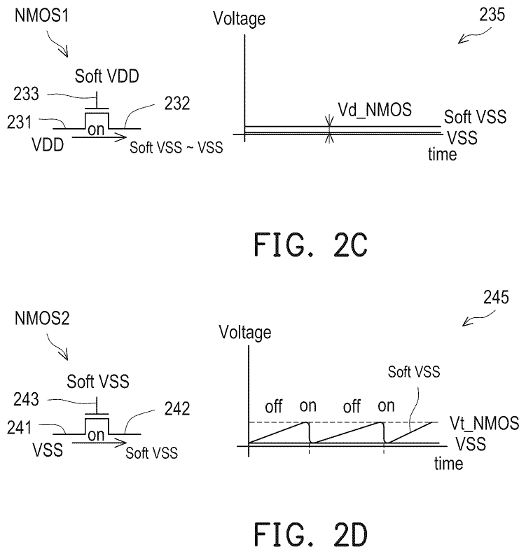

FIGS. 2A-2D include electric diagrams and voltage characteristics of various devices or transistors PMOS1, PMOS2, NMOS1, NMOS2 in one or more ECO cells, in accordance with some embodiments. In some embodiments, one or more of the transistors PMOS1, PMOS2, NMOS1, NMOS2 are included in an ECO cell. The transistors PMOS1, PMOS2, NMOS1, NMOS2 are sometimes referred to as driving transistors, and are configured to provide various soft power supply voltages for other devices or transistors in ECO cells in accordance with some embodiments.

In FIG. 2A, the transistor PMOS1 comprises source/drains 211, 212 and a gate 213. The source/drains and gate of a transistor are sometimes commonly referred to as terminals of the transistor. The source/drain 211 is configured to receive VDD. The source/drain 212 is configured to output a soft power supply voltage Soft VDD corresponding to VDD. The gate 213 is configured to receive VSS or a soft power supply voltage Soft VSS corresponding to VSS. Soft VSS is described with respect to one or more of FIGS. 2C, 2D. VDD is an example of one of a first power supply voltage and a second power supply voltage different from the first power supply voltage. VSS is an example of the other of the first power supply voltage and the second power supply voltage. Soft VDD is an example of one of a first voltage corresponding to the first power supply voltage and a second voltage corresponding to the second power supply voltage. Soft VSS is an example of the other of the first voltage and the second voltage.

FIG. 2A further includes a voltage characteristic 215 of the transistor PMOS1. In some embodiments, the gate 213 of the transistor PMOS1 is configured to receive VSS which turns ON the transistor PMOS1. In at least one embodiment, the gate 213 of the transistor PMOS1 is configured to receive Soft VSS which is either a constant voltage near VSS as described with respect to FIG. 2C, or a voltage hovering near VSS as described with respect to FIG. 2D. In some embodiments, regardless of whether Soft VSS is a constant voltage near VSS or a voltage hovering near VSS, Soft VSS is lower than a threshold voltage Vt_PMOS (described with respect to FIG. 2B) of a PMOS transistor such as the transistor PMOS1. As a result, the transistor PMOS1 is turned ON by VSS or Soft VSS at the gate 213. VDD supplied to the source/drain 211 is output, through the turned ON transistor PMOS1, as Soft VDD at the source/drain 212. Soft VDD at the source/drain 212 is a constant voltage near VDD. In at least one embodiment, a difference between Soft VDD at the source/drain 212 and VDD is a voltage drop Vd_PMOS across the transistor PMOS1 in the turned ON state. In at least one embodiment, the voltage drop Vd_PMOS is negligible and Soft VDD is substantially equal to VDD.

In FIG. 2B, the transistor PMOS2 comprises source/drains 221, 222 and a gate 223. The source/drain 221 is configured to receive VDD. The source/drain 222 is configured to output Soft VDD. The gate 223 is configured to receive Soft VDD. In at least one embodiment, the source/drain 222 and the gate 223 are electrically coupled to each other, so that Soft VDD output at the source/drain 222 is supplied to the gate 223 of the transistor PMOS2. In some embodiments, Soft VDD supplied to the gate 223 of the transistor PMOS2 is output from a transistor configured similarly to the transistor PMOS2. For simplicity, one or more operations of the transistor PMOS2 are described herein for embodiments where the source/drain 222 and the gate 223 are electrically coupled to each other. Embodiments where Soft VDD supplied to the gate 223 of the transistor PMOS2 is output from a transistor configured similarly to the transistor PMOS2 include similar operations.

FIG. 2B further includes a voltage characteristic 225 of the transistor PMOS2. Initially, a voltage at the gate 223 of the transistor PMOS2 is low, and the transistor PMOS2 is in the turned ON state when VDD is supplied to the source/drain 221, resulting in Soft VDD at the source/drain 222 being pulled up to VDD or a voltage level near VDD as described with respect to FIG. 2A. This state is shown at timing t1 in FIG. 2B. Soft VDD having a voltage level at or near VDD is supplied from the source/drain 222 to the gate 223, and turns OFF the transistor PMOS2. A conductive pattern (also referred to as a Soft VDD net) coupled to the source/drain 222 and configured to carry Soft VDD to the gate 223 and/or to further devices has parasitic coupling with one or more further adjacent conductive patterns (or nets). Due to this capacitive coupling, Soft VDD on the Soft VDD net is decreased, e.g., gradually, as shown in FIG. 2B. At timing t2, Soft VDD on the Soft VDD net (also at the gate 223) reaches the threshold voltage Vt_PMOS, and turns ON the transistor PMOS2. The transistor PMOS2 in the turned ON state causes VDD at the source/drain 221 to pull up Soft VDD at the source/drain 222 to VDD or a voltage level near VDD. The described process is then repeated. For example, the transistor PMOS2 is again turned OFF, Soft VDD on the Soft VDD net is again decreased until Soft VDD reaches the threshold voltage Vt_PMOS at timing t3 at which the transistor PMOS2 is momentarily turned ON to pull Soft VDD to VDD or a voltage level near VDD, and so on. Thus, Soft VDD output by the transistor PMOS2 at the source/drain 222 is a voltage hovering near VDD, or a voltage variable between VDD and the threshold voltage Vt_PMOS.

In FIG. 2C, the transistor NMOS1 comprises source/drains 231, 232 and a gate 233. The source/drain 231 is configured to receive VSS. The source/drain 232 is configured to output a soft power supply voltage Soft VSS corresponding to VSS. The gate 233 is configured to receive Soft VDD as described with respect to one or more of FIGS. 2A, 2B.

FIG. 2C further includes a voltage characteristic 235 of the transistor NMOS1. Soft VDD at the 233 of the transistor NMOS1 is either a constant voltage near VDD as described with respect to FIG. 2A, or a voltage hovering near VDD as described with respect to FIG. 2B. In some embodiments, regardless of whether Soft VDD is a constant voltage near VDD or a voltage hovering near VDD, Soft VDD is higher than a threshold voltage Vt_NMOS (described with respect to FIG. 2D) of an NMOS transistor such as the transistor NMOS1. As a result, the transistor NMOS1 is turned ON by Soft VDD at the gate 233. VSS supplied to the source/drain 231 is output, through the turned ON transistor NMOS1, as Soft VSS at the source/drain 232. Soft VSS at the source/drain 232 is a constant voltage near VSS. In at least one embodiment, a difference between Soft VSS at the source/drain 232 and VSS is a voltage drop Vd_NMOS across the transistor NMOS1 in the turned ON state.

In FIG. 2D, the transistor NMOS2 comprises source/drains 241, 242 and a gate 243. The source/drain 241 is configured to receive VSS. The source/drain 242 is configured to output Soft VSS. The gate 243 is configured to receive Soft VSS. In at least one embodiment, the source/drain 242 and the gate 243 are electrically coupled to each other, so that Soft VSS output at the source/drain 242 is supplied to the gate 243 of the transistor NMOS2. In some embodiments, Soft VSS supplied to the gate 243 of the transistor NMOS2 is output from a transistor configured similarly to the transistor NMOS2. For simplicity, one or more operations of the transistor NMOS2 are described herein for embodiments where the source/drain 242 and the gate 243 are electrically coupled to each other. Embodiments where Soft VSS supplied to the gate 243 of the transistor NMOS2 is output from a transistor configured similarly to the transistor NMOS2 include similar operations.

FIG. 2D further includes a voltage characteristic 245 of the transistor NMOS2. Initially, a voltage at the gate 243 of the transistor NMOS2 is low, and the transistor NMOS2 is in the turned OFF state, resulting in Soft VSS at the source/drain 242 being at or near VSS. This state is shown at timing t4 in FIG. 2D. A conductive pattern (also referred to as a Soft VSS net) coupled to the source/drain 242 and configured to carry Soft VSS to the gate 243 and/or to further devices has parasitic coupling with one or more further adjacent conductive patterns (or nets). Due to this capacitive coupling, Soft VSS on the Soft VSS net is increased, e.g., gradually, as shown in FIG. 2D. At timing t5, Soft VSS on the Soft VSS net (also at the gate 243) reaches the threshold voltage Vt_NMOS, and turns ON the transistor NMOS2. The transistor NMOS2 in the turned ON state causes VSS at the source/drain 241 to pull down Soft VSS at the source/drain 242 to VSS or a voltage level near VSS as described with respect to FIG. 2C. The described process is then repeated. For example, the transistor NMOS2 is again turned OFF, Soft VSS on the Soft VSS net is again increased until Soft VSS reaches the threshold voltage Vt_NMOS at timing t6 at which the transistor NMOS2 is momentarily turned ON to pull Soft VSS to VSS or a voltage level near VSS, and so on. Thus, Soft VSS output by the transistor NMOS2 at the source/drain 242 is a voltage hovering near VSS, or a voltage variable between VSS and the threshold voltage Vt_NMOS.

In some embodiments, at least one soft power supply voltage, such as Soft VDD or Soft VSS, output by one or more of the transistors PMOS1, PMOS2, NMOS1, NMOS2 in an ECO cell is supplied to one or more further devices in the ECO cell. In at least one embodiment, a soft power supply voltage is supplied to one or more source/drains in the ECO cell, thereby avoiding one or more issues related to floating source/drains and/or eliminating forbidden dummy devices described with respect to FIG. 1D from the ECO cell. In at least one embodiment, Soft VDD, rather than VDD, is supplied to a gate of a device in the ECO cell. As a result, it is possible to avoid a direct electrical connection between the gate and a VDD power rail, thereby avoiding or reducing ESD or antenna effect violation risks.

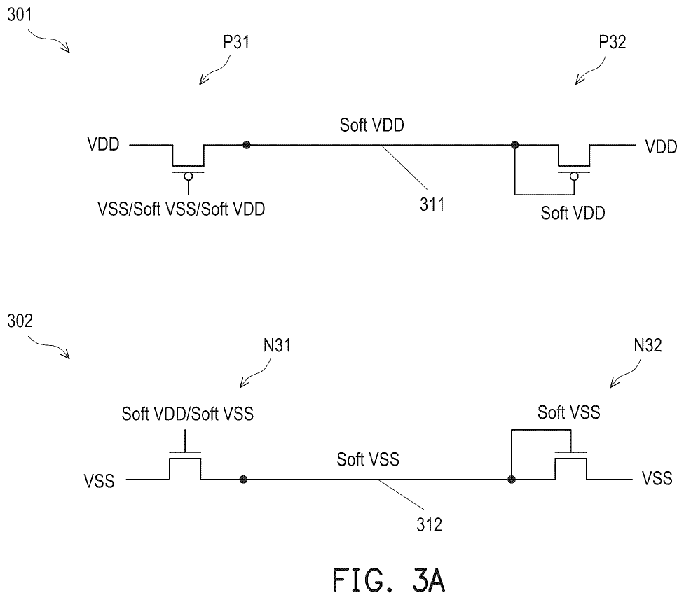

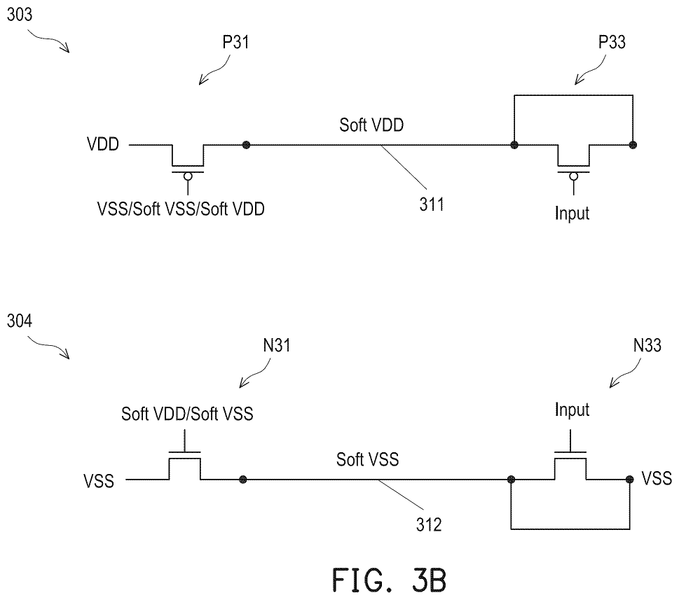

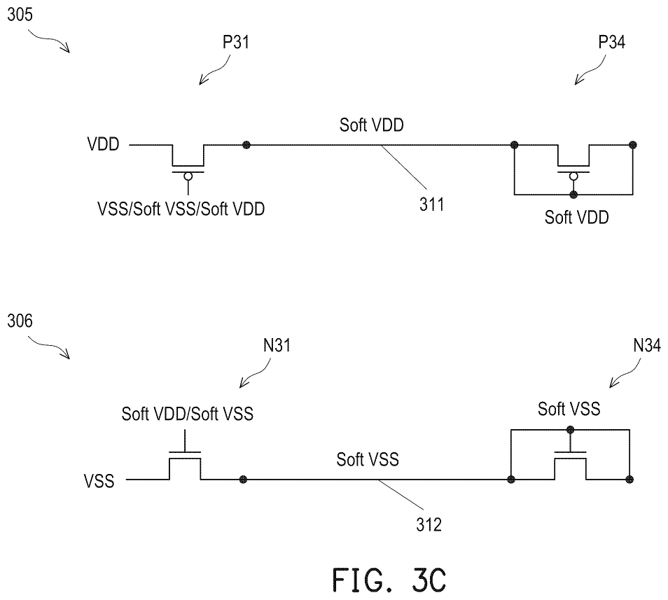

FIGS. 3A, 3B, 3C include electric diagrams of various example circuits 301-306 in one or more ECO cells, in accordance with some embodiments. In some embodiments, more than one of the circuits 301-306 and/or multiple instances of a circuit among the circuits 301-306 are included in an ECO cell. For simplicity, corresponding components in FIGS. 3A-3C are designated by the same reference numerals.

The circuit 301 in FIG. 3A includes PMOS transistors P31, P32. The transistor P31 has a source/drain configured to receive VDD, e.g., from a VDD power rail, a further source/drain coupled to a Soft VDD net 311, and a gate configured to receive VSS, Soft VSS or Soft VDD. When the gate of the transistor P31 is configured to receive VSS, e.g., from a VSS power rail, or Soft VSS, e.g., from a Soft VSS net, the transistor P31 corresponds to the transistor PMOS1 described with respect to FIG. 2A. When the gate of the transistor P31 is configured to receive Soft VDD, e.g., from a Soft VDD net, the transistor P31 corresponds to the transistor PMOS2 described with respect to FIG. 2B.

The transistor P32 has a source/drain configured to receive VDD, e.g., from a VDD power rail, and a further source/drain and a gate coupled to the transistor P31 through the Soft VDD net 311. Thus, the transistor P32 has two terminals coupled to receive Soft VDD. In some embodiments, the transistor P32 corresponds to the transistor PMOS2 described with respect to FIG. 2B where the gate 223 is electrically coupled to the source/drain 222.

In an example operation in accordance with some embodiments, when the gate of the transistor P31 is configured to receive VSS or Soft VSS, Soft VDD on the Soft VDD net 311 is a constant voltage near VDD as described with respect to FIG. 2A, and keeps the transistor P32 in the turned OFF state.

In a further example operation in accordance with some embodiments, when the gate of the transistor P31 is configured to receive Soft VDD, Soft VDD on the Soft VDD net 311 is a voltage hovering near VDD, and causes the transistor P32 to periodically turn ON momentarily and then turn OFF, as described with respect to FIG. 2B.

Other alternative configurations of the circuit 301 are within the scopes of various embodiments. For example, in some embodiments, instead of Soft VDD, VSS or Soft VSS is supplied to the gate of the transistor P32, in which case the electrical connection between the gate of the transistor P32 and the Soft VDD net 311 is omitted.

The circuit 302 in FIG. 3A is similar to the circuit 301, but includes NMOS transistors instead of PMOS transistors. Specifically, the circuit 302 includes NMOS transistors N31, N32. The transistor N31 has a source/drain configured to receive VSS, e.g., from a VSS power rail, a further source/drain coupled to a Soft VSS net 312, and a gate configured to receive Soft VDD or Soft VSS. When the gate of the transistor N31 is configured to receive Soft VDD, e.g., from a Soft VDD net, the transistor N31 corresponds to the transistor NMOS1 described with respect to FIG. 2C. When the gate of the transistor N31 is configured to receive Soft VSS, e.g., from a Soft VSS net, the transistor N31 corresponds to the transistor NMOS2 described with respect to FIG. 2D.

The transistor N32 has a gate configured to receive VSS, e.g., from a VSS power rail, and source/drains coupled to the transistor N31 through the Soft VSS net 312. Thus, the transistor N32 has two terminals coupled to receive Soft VSS. In some embodiments, the transistor N32 corresponds to the transistor NMOS2 described with respect to FIG. 2D where the gate 243 is electrically coupled to the source/drain 242.

In an example operation in accordance with some embodiments, when the gate of the transistor N31 is configured to receive Soft VDD, Soft VSS on the Soft VSS net 312 is a constant voltage near VSS as described with respect to FIG. 2C, and keeps the transistor N32 in the turned OFF state.

In a further example operation in accordance with some embodiments, when the gate of the transistor N31 is configured to receive Soft VSS, Soft VSS on the Soft VSS net 312 is a voltage hovering near VSS, and causes the transistor N32 to periodically turn ON momentarily and then turn OFF, as described with respect to FIG. 2D.

Other alternative configurations of the circuit 302 are within the scopes of various embodiments. For example, in some embodiments, instead of Soft VSS, Soft VDD is supplied to the gate of the transistor N32, in which case the electrical connection between the gate of the transistor N32 and the Soft VSS net 312 is omitted. In some embodiments, the circuits 301, 302 are example circuits that solves issues related to forbidden floating source/drain dummy devices.

The circuit 303 in FIG. 3B includes PMOS transistors P31, P33. The transistor P33 has source/drains coupled to the transistor P31 through the Soft VDD net 311, and a gate coupled to an input net. Thus, the transistor P33 has two terminals coupled to receive Soft VDD. A voltage at the input net does not affect operation of the circuit 303, because the source/drains of the transistor P33 are electrically coupled to each other, and configure the transistor P33 as a dummy device. In some embodiments, a voltage at the input net coupled to the gate of the transistor P33 is one of VSS, Soft VSS, Soft VDD.

The circuit 304 in FIG. 3B is similar to the circuit 303, but includes NMOS transistors instead of PMOS transistors. Specifically, the circuit 304 includes NMOS transistors N31, N33. The transistor N33 has source/drains coupled to the transistor N31 through the Soft VSS net 312, and a gate coupled to an input net. Thus, the transistor N33 has two terminals coupled to receive Soft VSS. A voltage at the input net does not affect operation of the circuit 304, because the source/drains of the transistor N33 are electrically coupled to each other, and configure the transistor N33 as a dummy device. In some embodiments, a voltage at the input net coupled to the gate of the transistor N33 is one of VSS, Soft VSS, Soft VDD.

In some embodiments, the circuits 303, 304 are example circuits that solves issues related to forbidden inverter dummy devices.

The circuit 305 in FIG. 3C includes PMOS transistors P31, P34. The transistor P34 has all three terminals, i.e., both source/drains and a gate, coupled to the transistor P31 through the Soft VDD net 311. The PMOS transistor P34 is configured as a dummy device.

The circuit 306 in FIG. 3C is similar to the circuit 305, but includes NMOS transistors instead of PMOS transistors. Specifically the circuit 306 comprises NMOS transistors N31, N34. The transistor N34 has all three terminals, i.e., both source/drains and a gate, coupled to the transistor N31 through the Soft VSS net 312. The NMOS transistor N34 is configured as a dummy device.

In some embodiments, the circuits 305, 306 are example circuits that solves issues related to forbidden output dummy devices.

In some embodiments, the inclusion of one or more of the circuits 301-306 or alternative configurations thereof in an ECO cell avoids one or more issues related to floating source/drains and/or ESD risks, and/or eliminates the forbidden dummy devices 181-188 from the ECO cell. Non-limiting example layouts of ECO cells including one or more of the circuits 301-306 are described with respect to FIGS. 4A, 4B, 4D.

FIG. 4A is a schematic view of a layout of an ECO cell 400A, in accordance with some embodiments. In some embodiments, the ECO cell 400A corresponds to a region in the circuit region 103 described with respect to FIG. 1A, and/or a region in the IC device 100B described with respect to FIG. 1B, and/or an ECO cell in the layout 100C described with respect to FIG. 1C. In at least one embodiment, the ECO cell 400A is an ECO cell initially placed in a layout of an IC device (hereinafter “IC layout”) to be later programmed (or replaced) when the IC layout is to be modified. In some embodiments, the ECO cell 400A is a programmed ECO cell that replaces another ECO cell, e.g., an ECO base cell, which was previously or initially placed in an IC layout, in order to modify the IC layout. In at least one embodiment, the ECO cell 400A is stored as a standard cell in a cell library on a non-transitory computer-readable medium.

The ECO cell 400A comprises active regions OD1, OD2 having different conductivity types. The active region OD1 is an example of one of a first active region of a first conductivity type, and a second active region of a second conductivity type different from the first conductivity type. The active region OD2 is an example of the other of the first active region and the second active region. In the example configuration in FIG. 4A, the first active region OD1 is a P-type active region, and the second active region OD2 is an N-type active region. In one or more embodiments, the first active region OD1 is an N-type active region, and the second active region OD2 is a P-type active region. The active regions OD1, OD2 extend along a first axis, i.e., X axis. The active regions OD1, OD2 include P-type dopants and/or N-type dopants to form one or more circuit elements or devices. Examples of circuit elements include, but are not limited to, transistors and diodes. Examples of transistors include, but are not limited to, metal oxide semiconductor field effect transistors (MOSFETs), complementary metal oxide semiconductor (CMOS) transistors, bipolar junction transistors (BJTs), high voltage transistors, high frequency transistors, P-channel and/or N-channel field effect transistors (PFETs/NFETs), FinFETs, planar MOS transistors with raised source/drains, nanosheet FETs, nanowire FETs, or the like. An active region configured to form one or more PMOS devices is sometimes referred to as a “PMOS active region.” An active region configured to form one or more NMOS devices is sometimes referred to as an “NMOS active region.”

The ECO cell 400A further comprises a plurality of gate regions or gates 410-418 extending continuously across the active regions OD1, OD2 along a second axis, i.e., Y axis, which is transverse to the X axis. In at least one embodiment, the Y axis is perpendicular to the X axis. Some of the gates 410-418 are conductive gates that, together with the active regions OD1, OD2, configure corresponding transistors. Other gates among the gates 410-418 are dielectric gates that do not form transistors with the active regions OD1, OD2. For example, the gates 411, 413, 414, 416, 417 are conductive gates each of which correspondingly configures, together with the active regions OD1, OD2, a PMOS transistor and an NMOS transistor having gates electrically coupled to each other. Specifically, the conductive gates 411, 413, 414, 416, 417 correspondingly form PMOS transistors P1-P5 with the active region OD1, and correspondingly form NMOS transistors N1-N5 with the active region OD2.

The gates 410, 412, 415, 418 are dielectric gates which are sometimes referred to as “CPODE”. In some embodiments, a dielectric gate corresponds to an insulation structure that extends in a thickness direction (e.g., the Z axis described with respect to FIG. 1B) through the underlying active region to physically and electrically separate two portions of the active region from each other. For example, the dielectric gate 412 corresponds to an insulation structure that physically and electrically separate a portion of the active region OD1 (or OD2) on the left side (in FIG. 4A) of the dielectric gate 412 from another portion of the active region OD1 (or OD2) on the right side of the dielectric gate 412. In other words, the dielectric gate 412 physically and electrically separates a source/drain of the transistor P1 (or N1) adjacent to the left side (in FIG. 4A) of the dielectric gate 412 from a source/drain of the transistor P2 (or N2) adjacent to the right side of the dielectric gate 412. The gates 410-418, including both conductive gates and dielectric gates, are arranged side by side along the X axis at an interval, or pitch, of 1 CPP, as described with respect to FIG. 1B.

In at least one embodiment, centerlines of the dielectric gates 410, 418 coincide with corresponding vertical edges of a boundary (not shown) of the ECO cell 400A. The vertical edges coinciding with the centerlines of the dielectric gates 410, 418 extend along the Y axis. The boundary of the ECO cell 400A corresponds to the boundary of an ECO cell, e.g., the cell C1, described with respect to FIG. 1C. In a placement operation in accordance with some embodiments, when the ECO cell 400A is placed to abut another cell (e.g., similarly to the cell C1 abutting the cell C2 in FIG. 1C), one of the dielectric gates 410, 418 is merged with a dielectric gate along a corresponding vertical edge of a boundary of the other cell. The boundary of the ECO cell 400A further comprises horizontal edges extending along the X axis. In some embodiments, the horizontal edges of the boundary of the ECO cell 400A coincide with centerlines of corresponding power rails as described with respect to FIG. 1C, and/or as described herein with respect to power tracks M0_VSS, M0_VDD. In some embodiments, various features of the ECO cell 400A as described herein, e.g., active regions, gates, MD contact structures, VD vias (except VDR vias as described herein), VG vias, M0 conductors (except power rails), or the like, are confined within the boundary of the ECO cell 400A.

The described configuration of the ECO cell 400A comprising two active regions OD1, OD2 immediately adjacent (or directly adjacent) each other along the Y axis is an example. Other cells in various embodiments include other numbers of active regions arranged along the Y axis. Two active regions are immediately adjacent along the Y axis when there is no other active region therebetween. The ECO cell 400A with two active regions has a single cell height (1 CH) as described with respect to FIG. 1C. In some embodiments, the cell height is a distance along the Y axis between the horizontal edges of the boundary of the ECO cell 400A, e.g., the distance along the Y axis between the power tracks M0_VSS, M0_VDD.

The ECO cell 400A further comprises MD contact structures 420-427 over corresponding source/drain regions of the transistors P1-P5 in the active region OD1, and MD contact structures 430-437 over corresponding source/drain regions of the transistors N1-N5 in the active region OD2. MD contact structures and gates are arranged alternatingly along the X axis. A pitch, i.e., a center-to-center distance along the X axis, between immediately adjacent MD contact structures is the same as the pitch CPP between immediately adjacent gates. In some embodiments, the shapes and/or sizes of MD contact structures are defined by one or more cut-MD (CMD) mask regions of a CMD mask. In the example configuration in FIG. 4A, three CMD mask regions 419, 429, 439 are shown. The CMD mask region 419 defines upper edges (in FIG. 4A) of the MD contact structures 420-427. The CMD mask region 439 defines lower edges (in FIG. 4A) of the MD contact structures 430-437. The CMD mask region 429 defines lower edges (in FIG. 4A) of the MD contact structures 420-427 and upper edges (in FIG. 4A) of the MD contact structures 430-437. Along the Y axis, the MD contact structures 420-427 are correspondingly aligned with, and separate by the CMD mask region 429 from, the MD contact structures 430-437.

The ECO cell 400A further comprises BCMD features of a logic operation layer BCMD. In the example configuration in FIG. 4A, three BCMD features along the upper horizontal edge of the boundary of the ECO cell 400A, e.g., along the power track M0_VDD, are commonly designated as BCMD features 428. Two BCMD features along the lower horizontal edge of the boundary of the ECO cell 400A, e.g., along the power track M0_VSS, are commonly designated as BCMD features 438. In a placement operation in accordance with some embodiments, when the ECO cell 400A is placed to abut another cell (e.g., similarly to the cell C1 abutting the cell C3 in FIG. 1C), one or more of the BCMD features 428 or one or more of the BCMD features 438 is merged with a corresponding BCMD feature along a corresponding horizontal edge of a boundary of the other cell.

The ECO cell 400A further comprises VG vias and VD vias over corresponding gates and MD contact structures. Some VD vias are configured for electrical connections with power rails, whereas other VD vias are not configured for electrical connections with power rails. Hereinafter, VD vias configured for electrical connections with power rails are referred to as VDR vias to differentiate from other VD vias not configured for electrical connections with power rails. In the example configuration in FIG. 4A, the ECO cell 400A comprises VDR vias 440, 442, 446 correspondingly over the MD contact structures 420, 422, 426 and the underlying source/drains, and configured for electrical connections with a VDD power rail along the power track M0_VDD. The ECO cell 400A further comprises VDR vias 441, 445 correspondingly over the MD contact structures 430, 436 and the underlying source/drains, and configured for electrical connections with a VSS power rail along the power track M0_VSS. The ECO cell 400A further comprises VD vias 451, 453, 454, 455, 457, 461, 462, 463, 464, 465, 466, 467 correspondingly over the MD contact structures 421, 423, 424, 425, 427, 431, 432, 433, 434, 435, 436, 437 and the underlying source/drains. The VDR vias have greater dimensions than the other VD vias along both X axis and Y axis. The ECO cell 400A further comprises VG vias 471, 473, 474, 476, 477 correspondingly over the conductive gates 411, 413, 414, 416, 417.

The ECO cell 400A further comprises conductive patterns, or conductors, in the M0 layer. For simplicity, M0 conductors are not fully illustrated in FIG. 4A, but are schematically illustrated by arrows. In the example configuration in FIG. 4A, the ECO cell 400A comprises, in the M0 layer, M0 conductors 481, 482, 483, 484 along corresponding tracks M0_1, M0_2, M0_3, M0_4. In functional circuits, functional cells, or ECO cells after being programmed, M0 conductors along the tracks M0_1, M0_2, M0_3, M0_4 are configured to transfer signals, e.g., data, control, clock, or the like, among various circuit elements of the IC device. Therefore, the tracks M0_1, M0_2, M0_3, M0_4 are sometimes referred to as signal tracks. The ECO cell 400A further comprises, in the M0 layer, a VSS power rail (not shown) and a VDD power rail (not shown) along corresponding tracks M0_VSS, M0_VDD. Therefore, the tracks M0_VSS, M0_VDD along which the power rails are arranged are sometimes referred to as power tracks. Both signal tracks and power tracks in the M0 layer are sometimes commonly referred to as M0 tracks.

The M0 tracks and the corresponding M0 conductors extend along the X axis and are spaced from each other along the Y axis. In some embodiments, an M0 track coincides with, or indicates, a center line of an M0 conductor arranged along the M0 track. In at least one embodiment, the power tracks M0_VSS, M0_VDD correspondingly coincide with the horizontal edges of the boundary of the ECO cell 400A. The described coincidences are examples, and other configurations are within the scopes of various embodiments. In some embodiments, the power rails extend continuously along the X axis across multiple cells in a circuit region, as described with respect to FIG. 1C, to supply VDD and VSS to such multiple cells. Power rails are longer (along the X axis) and wider (along the Y axis) than M0 conductors along signal tracks. In some embodiments, a pair of immediately adjacent power rails define therebetween a row of cells having a cell height of 1 CH. Two power rails (or power tracks) are immediately adjacent along the Y axis when there is no other power rail (or power track) therebetween. Similarly, two signal tracks are immediately adjacent along the Y axis when there is no other signal track therebetween. Further, two M0 tracks are immediately adjacent along the Y axis when there is no other M0 track therebetween. The number of four signal tracks M0_1, M0_2, M0_3, M0_4 between a pair of immediately adjacent power tracks M0_VSS, M0_VDD (or over a pair of one P-type active region and one N-type active region, or over a single cell height, i.e., 1 CH), is an example. Other configurations are within the scopes of various embodiments, as described herein.

In some embodiments, M0 conductors in the M0 layer belong to the same mask. In at least one embodiment, M0 conductors in the M0 layer are separated into several masks to meet one or more design and/or manufacturing requirements. For example, M0 conductors, including the VSS power rail, along the M0 tracks M0_VSS, M0_2, M0_4, belong to one mask sometimes referred to as “M0_A mask,” whereas M0 conductors, including the VDD power rail, along the M0 tracks M0_1, M0_3, M0_VDD belong to another mask sometimes referred to as “M0_B mask.”

In the example configuration in FIG. 4A, the M0 conductor 481 is over and electrically couples the VG via 476 and the VD vias 461, 462, 463, 464, 467. The M0 conductor 482 is over and electrically couples the VG vias 471, 473, 474 and the VD vias 465, 466. The M0 conductor 483 is over and electrically couples the VG via 477 and the VD via 451. The M0 conductor 484 is over and electrically couples the VD vias 453, 454, 455, 457. As a result, the transistors P1-P5 and N1-N5 are electrically coupled to as follows.

The transistor P1 has one source/drain electrically coupled to receive VDD from the VDD power rail through the MD contact structure 420 and the VDR via 440, and the gate 411 electrically coupled to receive VSS from the VSS power rail through the M0 conductor 482, the MD contact structure 436 and the VDR via 445. The transistor P1 corresponds to the transistor PMOS1 described with respect to FIG. 2A or the transistor P31 described with respect to FIGS. 3A-3C, and is configured to output Soft VDD from the other source/drain through the MD contact structure 421 to the M0 conductor 483.

The transistor P2, similarly to the transistor P1, has one source/drain electrically coupled to receive VDD from the VDD power rail, and the gate 413 electrically coupled to receive VSS from the M0 conductor 482. The transistor P2 corresponds to the transistor PMOS1 described with respect to FIG. 2A or the transistor P31 described with respect to FIGS. 3A-3C, and is configured to output Soft VDD from the other source/drain through the MD contact structure 423 to the M0 conductor 484.

The transistor P3 has both source/drains electrically coupled to receive Soft VDD from the M0 conductor 484, and the gate 414 electrically coupled to receive VSS from the M0 conductor 482. The transistor P3 corresponds to the transistor P33 described with respect to FIG. 3B. The transistor P3 is electrically coupled as a decoupling capacitor.

The transistor P4 has one source/drain electrically coupled to receive VDD from the VDD power rail through the MD contact structure 426 and the VDR via 446, and the gate 416 electrically coupled to receive Soft VSS from the M0 conductor 481 (described herein with respect to the transistor N5). The transistor P4 corresponds to the transistor PMOS1 described with respect to FIG. 2A or the transistor P31 described with respect to FIGS. 3A-3C, and is configured to output Soft VDD from the other source/drain through the MD contact structure 425 to the M0 conductor 484.

The transistor P5 has one source/drain electrically coupled to receive VDD from the VDD power rail, and the gate 417 electrically coupled to receive Soft VDD from the M0 conductor 483. The transistor P5 corresponds to the transistor PMOS2 described with respect to FIG. 2B or the transistor P31 described with respect to FIGS. 3A-3C, and is configured to output Soft VDD from the other source/drain through the MD contact structure 427 to the M0 conductor 484. An electric diagram of the transistors P4, P5 is also illustrated in FIG. 4A.

The transistor N1 has one source/drain electrically coupled to receive VSS from the VSS power rail through the MD contact structure 430 and the VDR via 441, and the gate 411 electrically coupled to receive VSS from the M0 conductor 482. The transistor N1 is always in the turned OFF state due to VSS at the gate 411.

The transistor N2 has both source/drains electrically coupled to receive Soft VSS from the M0 conductor 481, and the gate 413 electrically coupled to receive VSS from the M0 conductor 482. The transistor N2 corresponds to the transistor N33 described with respect to FIG. 3B.

The transistor N3, similarly to the transistor N2, has both source/drains electrically coupled to receive Soft VSS from the M0 conductor 481, and the gate 414 electrically coupled to receive VSS from the M0 conductor 482. The transistor N3 corresponds to the transistor N33 described with respect to FIG. 3B.

The transistor N4 has both source/drains electrically coupled to receive VSS from the M0 conductor 482, and the gate 416 electrically coupled to receive Soft VSS from the M0 conductor 481.

The transistor N5 has one source/drain electrically coupled to receive VSS from the VSS power rail through the MD contact structure 436 and the VDR via 445, and the gate 417 electrically coupled to receive Soft VDD from the M0 conductor 483. The transistor N5 corresponds to the transistor NMOS1 described with respect to FIG. 2C or the transistor N31 described with respect to FIGS. 3A-3C, and is configured to output Soft VSS from the other source/drain through the MD contact structure 437 to the M0 conductor 481.

In FIG. 4A, the arrow head of the arrow schematically designating the M0 conductor 481 indicates the direction in which power (i.e., Soft VSS) is supplied along the M0 conductor 481, i.e., from the source/drain of the transistor N5 under the MD contact structure 437 to the source/drain of the transistor N1 under the MD contact structure 431. The arrow head of the arrow schematically designating the M0 conductor 482 indicates the direction in which power (i.e., VSS) is supplied along the M0 conductor 482, i.e., from the source/drain under the MD contact structure 436 to the gate 411 of the transistors P1, N1. The arrow head of the arrow schematically designating the M0 conductor 483 indicates the direction in which power (i.e., Soft VDD) is supplied along the M0 conductor 483, i.e., from the source/drain of the transistor P1 under the MD contact structure 421 to the gate 417 of the transistors P5, N5. The two arrow heads of the double-headed arrow schematically designating the M0 conductor 484 indicates that power (i.e., Soft VDD) is supplied along the M0 conductor 484 from multiple sources, i.e., from the source/drains of the transistors P2, P4, P5 correspondingly under the MD contact structures 423, 425, 427.

The ECO cell 400A does not contain a device configured to perform a logic function. In some embodiments, the ECO cell 400A corresponds to an ECO base cell.

The ECO cell 400A does not contain any floating source/drain. In other words, the ECO cell 400A is free of floating source/drains. Specifically, all source/drains in the ECO cell 400A are electrically coupled to one of VDD, VSS, Soft VDD or Soft VSS. As a result, it is possible in one or more embodiments to avoid issues or concerns related to floating source/drains.

The ECO cell 400A does not contain any gate with a direct electrical connection to a positive power rail, such as a VDD power rail. In other words, the ECO cell 400A is free of gates that are directly connected to a positive power rail. A direct connection in accordance with some embodiments is one that is not affected or interrupted by switching or controlling any device (e.g., a transistor). For example, the connection of the M0 conductor 482 to the VSS power rail through the VD via 466, MD contact structure 436 and VDR via 445 is a direct connection, because it is not affected or interrupted by switching or controlling any device, e.g., the transistor N4 or the transistor N5. A permanent electrical connection is an example of a direct connection in one or more embodiments. Because the ECO cell 400A does not contain any gate with a direct electrical connection to a positive power rail, it is possible in one or more embodiments to avoid ESD or antenna violation risks associated with such direct connections. In some embodiments, this advantage is achievable by generating ESD-safe Soft VDD and Soft VSS as described with respect to one or more of FIGS. 2A-2D, and using Soft VDD and Soft VSS to tie-ON or tie-OFF various devices, as described with respect to one or more of FIGS. 3A-3C, 4A.

None of the forbidden dummy devices 181-188 are included in the ECO cell 400A. This is an improvement over other approaches in accordance with which it is difficult or impossible to eliminate all forbidden dummy devices 181-188, especially where there is a limitation of four signal tracks over a single cell height (1 CH). To eliminate all forbidden dummy devices 181-188, the other approaches require an ECO cell with an increased size along the X axis, or require multiple ECO cells. In either case, the chip area or cell area will be disadvantageously increased. A further attempt in accordance with the other approaches to eliminate all forbidden dummy devices 181-188 includes using routing resources from higher layers, e.g., M1 conductors, V0 vias, or the like. This attempt disadvantageously takes away routing resources that would otherwise be available for other tasks or circuits. The described issues and/or disadvantages experienced in the other approaches are avoidable by one or more ECO cells in accordance with some embodiments. For example, even with the limitation of four signal tracks over a single cell height (1 CH), it is possible to eliminate all forbidden dummy devices 181-188 in the ECO cell 400A, without increasing the size or number of ECO cells and without using routing resources above the M0 layer (e.g., without using M1 conductors), thereby achieving advantages including, but not limited to, chip area improvement, increased flexibility and/or utility in ECO cell designs, or the like.

In some embodiments, when an ECO base cell or a previously placed ECO cell is programmed, various layers remain unchanged. For example, active regions, gates (including conductive gates and dielectric gates), any cut-gate mask regions for defining gate length and/or shape, MD contact structures, CMD mask regions, BCMD features remain unchanged in one or more embodiments. In other words, the active regions, gates and MD contact structures of an ECO base cell or a previously placed ECO cell are correspondingly identical to the active regions, gates and MD contact structures of a programmed ECO cell that replaces the ECO base cell or previously placed ECO cell. The programming of an ECO cell comprises changing one or more layers over the active regions, gates and MD contact structures. In some embodiments, the programming of an ECO cell comprises changes in one or more layers including VDR vias, VD vias, VG vias, the M0 layer, one or more cut-M0 masks, and the V0 layer. For example, a set of via structures and/or a set of M0 conductors in an ECO base cell or a previously placed ECO cell is/are replaced with another set of via structures and/or another sets of M0 conductors of a programmed ECO cell. Non-limiting examples of programmed ECO cells are described with respect to FIGS. 4B, 4D.

FIG. 4B is a schematic view of a layout of an ECO cell 400B, in accordance with some embodiments. In some embodiments, the ECO cell 400B corresponds to a region in the circuit region 103 described with respect to FIG. 1A, and/or a region in the IC device 100B described with respect to FIG. 1B, and/or an ECO cell in the layout 100C described with respect to FIG. 1C. In some embodiments, the ECO cell 400B is a programmed ECO cell that replaces another ECO cell, e.g., an ECO base cell, which was previously or initially placed in an IC layout, in order to modify the IC layout. For example, the ECO cell 400B is obtained by programming the ECO cell 400A, in one or more embodiments. In at least one embodiment, the ECO cell 400B is stored as a standard cell in a cell library on a non-transitory computer-readable medium. For simplicity, corresponding components in FIGS. 4A, 4B are designated by the same reference numerals.

Compared to the ECO cell 400A which is not configured to provide a logic function, the ECO cell 400B is programmed or configured to provide a function of an inverter. In some embodiments, as described herein, the active regions OD1, OD2, the gates 410-418, the MD contact structures 420-427, 430-437, the CMD mask regions 419, 429, 439, and the BCMD features 428, 438 in the ECO cell 400A are identical to the corresponding active regions, gates, MD contact structures, CMD mask regions, and BCMD features in the ECO cell 400B. The ECO cell 400B differs from the ECO cell 400A in one or more layers above the active regions, gates and MD contact structures, such as VD, VG, M0, or the like.

The ECO cell 400B comprises VD vias 451B, 453, 454, 455, 457, 461, 462, 463, 464, 465B, 466, 467 correspondingly over the MD contact structures 421, 423, 424, 425, 427, 431, 432, 433, 434, 435, 436, 437 and the underlying source/drains. The VD via 451B in the ECO cell 400B is over the track M0_4, whereas the corresponding VD via 451 in the ECO cell 400A is over the track M0_3. The VD via 465B in the ECO cell 400B is over the track M0_1, whereas the corresponding VD via 465 in the ECO cell 400A is over the track M0_2.

The ECO cell 400B further comprises VG vias 471B, 473B, 474B, 476B, 477B correspondingly over the conductive gates 411, 413, 414, 416, 417. The VG vias 471B, 473B, 474B in the ECO cell 400B are over the track M0_3, whereas the corresponding VG vias 471, 473, 474 in the ECO cell 400A are over the track M0_2. The VG via 476B in the ECO cell 400B is over the track M0_3, whereas the corresponding VG via 476 in the ECO cell 400A is over the track M0_1. The VG via 477B in the ECO cell 400B is over the track M0_2, whereas the corresponding VG via 477 in the ECO cell 400A is over the track M0_3.

The ECO cell 400B further comprises, in the M0 layer, M0 conductors 481B, 482B, 483B, 484B along corresponding tracks M0_1, M0_2, M0_3, M0_4. The M0 conductor 481B is over and electrically couples the VD vias 461, 462, 463, 464, 465B. The M0 conductor 482B is over and is electrically coupled to the VG via 477B. The M0 conductor 483B is over and electrically couples the VG vias 471B, 473B, 474B, 476B. The M0 conductor 484B is over and electrically couples the VD vias 451B, 453, 454, 455.

The ECO cell 400B further comprises cut-M0 (CM0) mask regions 491, 492, 494, 495. A CM0 mask region is configured to physically and electrically separate M0 conductors along the same M0 track. For example, the CM0 mask region 491 physically and electrically separates the M0 conductor 481B on the track M0_1 and on the left side (in FIG. 4B) of the CM0 mask region 491 from another M0 conductor (not shown) on the same track M0_1 and on the right side (in FIG. 4B) of the CM0 mask region 491. In some embodiments, the CM0 mask region 491 defines the right edge (in FIG. 4B) of the M0 conductor 481B. The CM0 mask region 492 physically and electrically separates the M0 conductor 482B on the track M0_2 and on the right side (in FIG. 4B) of the CM0 mask region 492 from another M0 conductor (not shown) on the same track M0_2 and on the left side (in FIG. 4B) of the CM0 mask region 492. In some embodiments, the CM0 mask region 492 defines the left edge (in FIG. 4B) of the M0 conductor 482B. Similarly, the CM0 mask regions 494, 495 physically and electrically separate M0 conductors on the track M0_4. In some embodiments, the CM0 mask regions 494, 495 correspondingly define the left and right edges (in FIG. 4B) of the M0 conductor 484B.

The ECO cell 400B further comprises V0 vias 401, 402, 404, 405, and M1 conductors 403, 406. The V0 via 401 is over the M0 conductor 483B, the V0 via 402 is over the M0 conductor 481B, and the M1 conductor 403 is over the V0 vias 401, 402. As a result, the M0 conductor 481B is electrically coupled to the M0 conductor 483B by the V0 vias 401, 402 and the M1 conductor 403.

The V0 via 404 is over an M0 conductor (not shown) which is on the track M0_4 and over the VD via 457. The V0 via 405 is over an M0 conductor (not shown) which is on the track M0_1 and over the VD via 467. The M1 conductor 406 is over the V0 vias 404, 405. As a result, the source/drain of the transistor P5 under the MD contact structure 427 is electrically coupled to the source/drain of the transistor N5 under the MD contact structure 437 by the VD vias 457, 467, corresponding M0 conductors (not shown), the V0 vias 404, 405 and the M1 conductor 406. The other source/drains of the transistors P5, N5 under the MD contact structures 426, 436 are correspondingly electrically coupled to the VDD power rail and the VSS power rail, as described herein.

Thus, the transistors P5, N5 are electrically coupled into an inverter having an input (IN) corresponding to the M0 conductor 482B, and an output (ZN) corresponding to the M1 conductor 406. The ECO cell 400B is programmed or configured to provide a function of an inverter. The inverter configured by the transistors P5, N5 is routed to one or more further circuits or cells by one or more further vias and/or conductors. The remaining transistors P1-P4, N1-N4 of the ECO cell 400B are electrically coupled as follows to avoid floating source/drains, forbidden dummy devices, and direct electrical connections of gates to a VDD power rail.

The transistor P1 has one source/drain electrically coupled to receive VDD from the VDD power rail through the MD contact structure 420 and the VDR via 440. The gate 411 of the transistor P1 is electrically coupled to receive Soft VSS from the M0 conductor 483B which, in turn, receives Soft VSS from the transistors N1, N4 (described herein below) through the M0 conductor 481B, the V0 vias 401, 402 and the M1 conductor 403. The transistor P1 corresponds to the transistor PMOS1 described with respect to FIG. 2A or the transistor P31 described with respect to FIGS. 3A-3C, and is configured to output Soft VDD from the other source/drain through the MD contact structure 421 to the M0 conductor 484B.

The transistor P2, similarly to the transistor P1, has one source/drain electrically coupled to receive VDD from the VDD power rail, and the gate 413 electrically coupled to receive Soft VSS from the M0 conductor 483B. The transistor P2 corresponds to the transistor PMOS1 described with respect to FIG. 2A or the transistor P31 described with respect to FIGS. 3A-3C, and is configured to output Soft VDD from the other source/drain through the MD contact structure 423 to the M0 conductor 484B.

The transistor P3 has both source/drains electrically coupled to receive Soft VDD from the M0 conductor 484B, and the gate 414 electrically coupled to receive Soft VSS the M0 conductor 483B. The transistor P3 corresponds to the transistor P33 described with respect to FIG. 3B. The transistor P3 is electrically coupled as a decoupling capacitor.

The transistor P4 has one source/drain electrically coupled to receive VDD from the VDD power rail through the MD contact structure 426 and the VDR vias 446, and the gate 416 electrically coupled to receive Soft VSS from the M0 conductor 483B. The transistor P4 corresponds to the transistor PMOS1 described with respect to FIG. 2A or the transistor P31 described with respect to FIGS. 3A-3C, and is configured to output Soft VDD from the other source/drain through the MD contact structure 425 to the M0 conductor 484B.

The transistor N1 has one source/drain electrically coupled to receive VSS from the VSS power rail through the MD contact structure 430 and the VDR vias 441, and the gate 411 electrically coupled to receive Soft VSS from the M0 conductor 483B. The transistor N1 corresponds to the transistor NMOS2 described with respect to FIG. 2D or the transistor N32 described with respect to FIG. 3A, and is configured to output Soft VSS from the other source/drain through the MD contact structure 431 to the M0 conductor 481B.

The transistor N2 has both source/drains electrically coupled to receive Soft VSS from the M0 conductor 481B, and the gate 413 electrically coupled to receive Soft VSS from the M0 conductor 483B. The transistor N2 corresponds to the transistor N34 described with respect to FIG. 3C.

The transistor N3, similarly to the transistor N2, has both source/drains electrically coupled to receive Soft VSS from the M0 conductor 481B, and the gate 414 electrically coupled to receive Soft VSS from the M0 conductor 483B. The transistor N3 corresponds to the transistor N34 described with respect to FIG. 3C.

The transistor N4 has one source/drain electrically coupled to receive VSS from the VSS power rail through the MD contact structure 436 and the VDR vias 445, and the gate 416 electrically coupled to receive Soft VSS from the M0 conductor 483B. The transistor N4 corresponds to the transistor NMOS2 described with respect to FIG. 2D or the transistor N32 described with respect to FIG. 3A, and is configured to output Soft VSS from the other source/drain through the MD contact structure 435 to the M0 conductor 481B. One or more advantages described herein are achievable by the ECO cell 400B, in accordance with some embodiments.

FIG. 4C includes electric diagrams of various devices, i.e., the transistors P3-P5, N3-N5, in the ECO cell 400B, in accordance with some embodiments. For simplicity, corresponding components in FIGS. 4B, 4C are designated by the same reference numerals.

The transistors P5, N5 are electrically coupled into an inverter having an input IN corresponding to the M0 conductor 482B, and an output ZN corresponding to the M1 conductor 406.

The transistors P3, P4, N3, N4 are not configured to provide a logic function, and are electrically coupled to avoid floating source/drains, forbidden dummy devices, and direct electrical connections of gates to a VDD power rail, as described with respect to FIG. 4B. A circuit comprising transistors P4, P3 corresponds to the circuit 303 described with respect to FIG. 3B, with the transistors P4, P3 corresponding to the transistors P31, P33, and the M0 conductor 484B corresponding to the Soft VDD net 311. A circuit comprising transistors N4, N3 corresponds to the circuit 306 described with respect to FIG. 3C, with the transistors N4, N3 corresponding to the transistors N31, N34, and the M0 conductor 481B corresponding to the Soft VSS net 312. As can be seen from FIG. 4C, the transistors P3, P4, N3, N4 are free of floating source/drains, forbidden dummy devices, and direct electrical connections of gates to a VDD power rail, thereby achieving one or more advantages described herein, in one or more embodiments.

FIG. 4D is a schematic view of a layout of an ECO cell 400D, in accordance with some embodiments. In some embodiments, the ECO cell 400D corresponds to a region in the circuit region 103 described with respect to FIG. 1A, and/or a region in the IC device 100B described with respect to FIG. 1B, and/or an ECO cell in the layout 100C described with respect to FIG. 1C. In some embodiments, the ECO cell 400D is a programmed ECO cell that replaces another ECO cell, e.g., an ECO base cell, which was previously or initially placed in an IC layout, in order to modify the IC layout. For example, the ECO cell 400D is obtained by programming the ECO cell 400A or the ECO cell 400B, in one or more embodiments. In at least one embodiment, the ECO cell 400D is stored as a standard cell in a cell library on a non-transitory computer-readable medium. For simplicity, corresponding components in FIGS. 4A, 4C, 4D are designated by the same reference numerals.

Compared to the ECO cell 400B which comprises an inverter configured by one pair of transistors (e.g., the transistors P5 and N5), the ECO cell 400D comprises an inverter configured by two pairs of transistors (e.g., the transistors P4 and N4, and transistors P5 and N5). The inverter in the ECO cell 400B has a driving strength of 1, whereas the inverter in the ECO cell 400D has a driving strength of 2. In some embodiments, as described herein, the active regions OD1, OD2, the gates 410-418, the MD contact structures 420-427, 430-437, the CMD mask regions 419, 429, 439, and the BCMD features 428, 438 in the ECO cell 400D are identical to the corresponding active regions, gates, MD contact structures, CMD mask regions, and BCMD features in the ECO cells 400A, 400B. The ECO cell 400D differs from the ECO cells 400A, 400B in one or more layers above the active regions, gates and MD contact structures, such as VD, VG, M0, or the like.

The ECO cell 400D comprises the same set of VD vias as the ECO cell 400B, including VD vias 451B, 453, 454, 455, 457, 461, 462, 463, 464, 465B, 466, 467 correspondingly over the MD contact structures 421, 423, 424, 425, 427, 431, 432, 433, 434, 435, 436, 437 and the underlying source/drains.

The ECO cell 400D further comprises VG vias 471B, 473B, 474D, 476B, 477D correspondingly over the conductive gates 411, 413, 414, 416, 417. The VG via 477D in the ECO cell 400D is over the track M0_3, whereas the corresponding VG via 477B in the ECO cell 400B is over the track M0_2.

The ECO cell 400D further comprises, in the M0 layer, M0 conductors 481D, 483D, 484D, 489 along corresponding tracks M0_1, M0_3, M0_4, M0_3. The M0 conductor 481D is shorter than the M0 conductor 481B in the ECO cell 400B, and is over and electrically couples the VD vias 461, 462, 463, 464. The M0 conductor 483D shorter than the M0 conductor 483B in the ECO cell 400B, and is over and electrically couples the VG vias 471B, 473B, 474B. The M0 conductor 484D is shorter than the M0 conductor 484B in the ECO cell 400B, and over and electrically couples the VD vias 451B, 453, 454. The M0 conductor 489 is over and electrically couples the VG vias 476B, 477D.

The ECO cell 400D further comprises cut-M0 (CM0) mask regions 494, 496, 497. Unlike the CM0 mask regions 491, 492, 494, 495 each of which is configured to cut or separate M0 conductors along one M0 tracks, each of the CM0 mask regions 496, 497 is elongated along the Y axis and is configured to cut or separate M0 conductors along two M0 tracks, in the same M0 mask. For example, the CM0 mask region 496 is configured to cut M0 conductors along the tracks M0_2, M0_4 which belong to the same M0_A mask. The CM0 mask region 496 is not configured to cut M0 conductors along the track M0_3. The CM0 mask region 497 is configured to cut M0 conductors along the tracks M0_1, M0_3 which belong to the same M0_B mask. The CM0 mask region 497 is not configured to cut M0 conductors along the track M0_2.

Specifically, the CM0 mask region 496 physically and electrically separates the M0 conductor 484D on the track M0_4 and on the left side (in FIG. 4D) of the CM0 mask region 496 from another M0 conductor (not shown) which is over the VD vias 455, 457, on the same track M0_4 and on the right side (in FIG. 4D) of the CM0 mask region 496. In some embodiments, the CM0 mask regions 494, 496 correspondingly define the left and right edges (in FIG. 4D) of the M0 conductor 484D.

The CM0 mask region 497 physically and electrically separates the M0 conductor 483D on the track M0_3 and on the left side (in FIG. 4D) of the CM0 mask region 497 from the M0 conductor 489 on the same track M0_3 and on the right side (in FIG. 4D) of the CM0 mask region 497. The CM0 mask region 497 physically and electrically separates the M0 conductor 481D on the track M0_1 and on the left side (in FIG. 4D) of the CM0 mask region 497 from another M0 conductor (not shown) which is over the VD vias 465B, 467, on the same track M0_1 and on the right side (in FIG. 4D) of the CM0 mask region 497. In some embodiments, the CM0 mask region 497 defines the right edges (in FIG. 4D) of the M0 conductors 481D, 438D, and also defines the left edge (in FIG. 4D) of the M0 conductor 489.

The ECO cell 400D further comprises V0 vias 401, 402, 404, 405, and M1 conductors 403, 406 as described with respect to the ECO cell 400B.

The M1 conductor 403 electrically couples the M0 conductor 481D and the M0 conductor 483D. The source/drains of the transistors P4, P5 correspondingly under the MD contact structures 425, 427 are electrically coupled to the source/drains of the transistors N4, N5 correspondingly under the MD contact structures 435, 437 by the VD vias 455, 457, 465B, 467, corresponding M0 conductors (not shown), the V0 vias 404, 405 and the M1 conductor 406.

Thus, the transistors P4, P5 are electrically coupled in parallel with each other. The transistors N4, N5 are electrically coupled in parallel with each other. The transistors P4, P5, N4, N5 are electrically coupled into an inverter having an input (IN) corresponding to the M0 conductor 489, and an output (ZN) corresponding to the M1 conductor 406. The remaining transistors P1-P3, N1-N3 of the ECO cell 400D are electrically coupled as described with respect to the ECO cell 400B, thereby avoiding floating source/drains, forbidden dummy devices, and direct electrical connections of gates to a VDD power rail. One or more advantages described herein are achievable by the ECO cell 400D, in accordance with some embodiments.

In the non-limiting example configurations in FIGS. 4B, 4D, the ECO cells 400B, 400D are configured or programmed as inverter cells. This is an example, and other functional cells configurable or programmable from ECO cells are within the scope of various embodiments. Examples of such cells include, but are not limited to, a logic gate cell, a memory cell, or the like. Examples of logic gate cells include, but are not limited to, AND, OR, NAND, NOR, XOR, INV, AND-OR-Invert (AOI), OR-AND-Invert (OAI), MUX, Flip-flop, BUFF, Latch, delay, clock, or the like. Examples of memory cells include, but are not limited to, a static random access memory (SRAM), a dynamic RAM (DRAM), a resistive RAM (RRAM), a magnetoresistive RAM (MRAM), a read only memory (ROM) cell, or another type of cell capable of having multiple states representative of logical values. In the example configurations in FIGS. 4B, 4D, the ECO cells 400B, 400D are inverters with a driving strength of 1 or 2. Other driving strengths, e.g., 3, 4, 6, or the like, are within the scopes of various embodiments.

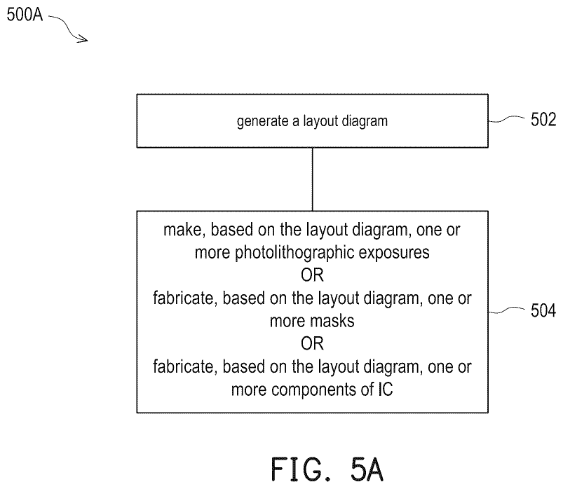

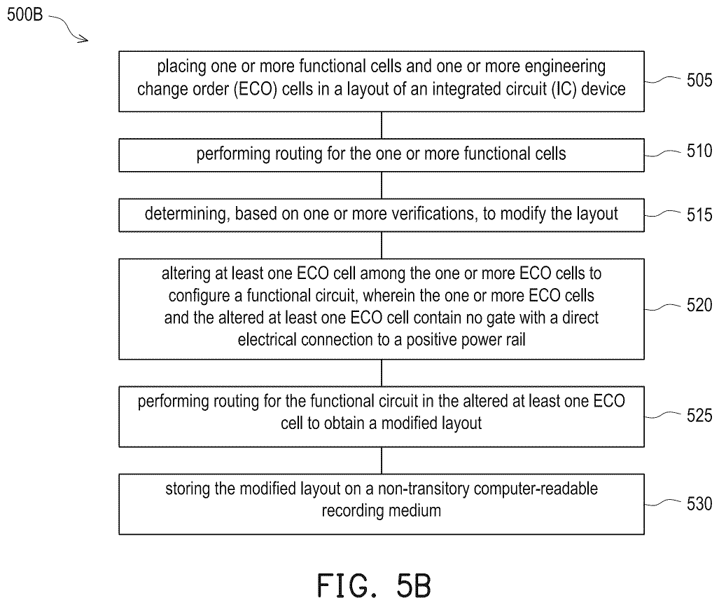

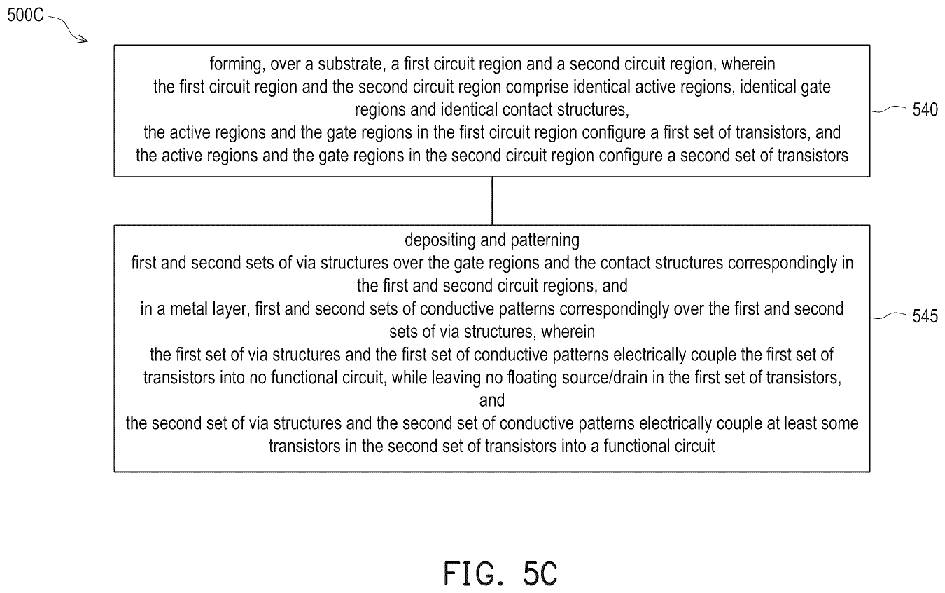

FIG. 5A is a flowchart of a method 500A of generating a layout and using the layout to manufacture an IC device, in accordance with some embodiments. Method 500A is implementable, for example, using an EDA system and/or an integrated circuit (IC) manufacturing system as described herein, in accordance with some embodiments. Regarding method 500A, examples of the layout include the layouts disclosed herein, or the like. Examples of an IC device to be manufactured according to method 500A include the IC devices 100A, 100B, 100C and/or one or more IC devices including one or more circuit regions corresponding to one or more ECO cells as described herein. Method 500A comprises operations 502, 504.

At operation 502, a layout is generated which, among other things, includes at least one ECO cell, as described herein. Examples of operation 502 are described with respect to FIG. 5B.

At operation 504, based on the layout, at least one of (A) one or more photolithographic exposures are made or (B) one or more semiconductor masks are fabricated or (C) one or more components in a layer of an IC device are fabricated. Examples of operation 504 are described with respect to FIG. 5C.

FIG. 5B is a flowchart of a method 500B of generating a layout for an IC device. The method 500B is performed at least partially by a processor. In some embodiments, the method 500B is performed to generate a layout including one or more ECO cells, as described herein. The method 500B comprises operations 505, 510, 515, 520, 525, 530.

At operation 505, one or more functional cells and one or more engineering change order (ECO) cells are placed in a layout of an integrated circuit (IC) device. For example, as described with respect to FIG. 1C, in a placement operation, one or more functional cells C2, C3, C4 and one or more ECO cells C1, C5 are placed in a layout, with some cells abutting one or more other cells. In at least one embodiment, the placement operation is performed by an APR tool or system, as described herein. In some embodiments, the one or more ECO cells include at least one ECO base cell which is not configured to provide any logic function, i.e., not configured to include any functional circuit. In some embodiments, the one or more ECO cells include at least one ECO cell which is already configured to provide a function, i.e., already includes a functional circuit. In an example, the one or more ECO cells include the ECO cell 400A.

At operation 510, a routing operation is performed for the one or more functional cells. For example, in a routing operation performed by an APR tool or system, via structures in various via layers and conductive patterns in various metal layers are generated to define electrical connections among circuits of the placed one or more functional cells. A resulting arrangement corresponds to the redistribution structure 150 described with respect to FIG. 1B. In at least one embodiment, routing is not generated for the one or more ECO cells, because the one or more ECO cells are not yet configured to provide a function and/or because any functional circuit in the one or more ECO cells is not yet required to be included in the layout.

At operation 515, a determination is made, based on one or more verifications, to modify the layout. Examples of verifications include, but are not limited to, a layout-versus-schematic (LVS) check, a design rule check (DRC), a simulation, or the like. An LVS check is performed, e.g., by an EDA tool, to ensure that the generated layout corresponds to a desired IC design based on which the layout is generated. A DRC is performed, e.g., by an EDA tool, to ensure that the layout satisfies certain manufacturing design rules, i.e., to ensure manufacturability of the IC device. A simulation is performed by a simulation tool, i.e., an EDA tool, to determine, taking parasitic resistance and parasitic capacitance extracted from the layout into account, whether the layout meets a predetermined specification, e.g., one or more predetermined timing requirements. In response to one or more evaluations, checks and/or simulations indicating one or more yield and/or performance concerns, and a determination is made to modify the layout. An approach for modifying the layout is to perform programing and routing for at least one of the previously placed ECO cells, as described with respect to operations 520, 525.

At operation 520, at least one ECO cell among the one or more ECO cells is altered to configure a functional circuit, wherein the one or more ECO cells and the altered at least one ECO cell contain no gate with a direct electrical connection to a positive power rail. For example, as described with respect to FIGS. 4A, 4B, 4D, the ECO cell 400A which is a previously placed ECO cell is programmed to include a functional circuit, e.g., an inverter, and becomes the programmed ECO cell 400B or 400D. The functional circuit in the programed ECO cell is configured, in one or more embodiments, to improve performance of the IC device being designed. The programming of an ECO cell comprises altering, in the ECO cell, one or more layers above active regions, gate regions and MD contact structures, while maintaining the active regions, gate regions and MD contact structures of the ECO cell unchanged. In at least one embodiment, as described with respect to FIGS. 4A, 4B, 4D, the programming of an ECO cell comprises generating or modifying one or more sets of VD vias, VG vias, or M0 conductors in the ECO cell being programmed.

As also described herein, e.g., with respect to FIGS. 4A, 4B, 4D, the one or more ECO cells initially placed in the placement operation at operation 505 and the altered ECO cell programmed at operation 520 contain no gate with a direct electrical connection to a positive power rail. As a result, it is possible in one or more embodiments to avoid or reduce ESD or antenna violation risks during fabrication of IC devices based on the layout.

At operation 525, a further routing operation is performed for the functional circuit in the altered at least one ECO cell to obtain a modified layout. For example, one or more via structures and/or conductive patterns are generated to electrically couple the functional circuit (e.g., the inverter in the ECO cell 400B, 400D) of the altered or programmed ECO cell with other circuits in other cells of the layout. The described modification of the layout is performed, in one or more embodiments, simply by altering or reconfiguring only one or more sets of vias and/or conductive patterns in an ECO cell and routing the reconfigured ECO cell, without rearranging the functional cells already placed in the layout. As a result, costs required for modifying the layout are reduced while improving performance of IC devices corresponding to the modified layout.

At operation 530, the modified layout of the IC device is stored on a non-transitory computer-readable recording medium, e.g., for later retrieval and use in manufacturing IC devices, as described with respect to FIG. 5C. One or more advantages described herein are achievable by a layout generated by the method 500B and/or by IC devices manufactured based on such layout, in accordance with some embodiments.

FIG. 5C is a flowchart of a method 500C of manufacturing an IC device, in accordance with some embodiments. In some embodiments, the method 500C is performed to manufacture an IC device corresponding to one or more IC devices and/or layouts described herein. The method 500C comprises operations 540, 544.

At operation 540, a first circuit region and a second circuit region are formed over a substrate. The formation comprises forming identical active regions, identical gate regions and identical contact structures in the first circuit region and the second circuit region. The active regions and the gate regions in the first circuit region configure a first set of transistors, and the active regions and the gate regions in the second circuit region configure a second set of transistors.

For example, as described with respect to FIG. 1B, an example active region (OD) is formed along the X axis over a substrate 110. In some embodiments, the active region includes one or more of a semiconductor material, e.g., silicon (Si), silicon-germanium (SiGe), silicon-carbide (SiC), or the like, a dopant material, e.g., boron (B), phosphorous (P), arsenic (As), gallium (Ga), or another suitable material. In some embodiments, an active region comprises a nano-sheet structure, e.g., a continuous volume of one or more layers of one or more semiconductor materials. In various embodiments, individual nano-sheet layers include a single monolayer or multiple monolayers of a given semiconductor material. Example gates 111, 113, 115 are formed to extend over the active region (OD) to configure therewith various transistors. In some embodiments, a gate is a part of a gate structure and includes one or more conductive materials, e.g., polysilicon, copper (Cu), aluminum (Al), tungsten (W), cobalt (Co), ruthenium (Ru), or one or more other metals or other suitable materials. The gate structure further comprises a gate dielectric layer including one or more insulating materials, e.g., silicon dioxide, silicon nitride (Si₃N₄), and/or one or more other suitable material such as a low-k material having a k value less than 3.8, or a high-k material having a k value greater than 3.8, such as aluminum oxide (Al₂O₃), hafnium oxide (HfO₂), tantalum pentoxide (Ta₂O₅), or titanium oxide (TiO₂). Example MD contact structures 131, 132, 133, 134 are also formed to extend over the active region (OD) to provide electrical connections to source/drains in the active region. In some embodiments, the MD contact structures 131, 132, 133, 134 comprise a metal.

In some embodiments, the first circuit region corresponds to the cell C1 in FIG. 1C and the ECO cell 400A in FIG. 4A, whereas the second circuit region corresponds to the cell C5 in FIG. 1C and the ECO cell 400B in FIG. 4B (or the ECO cell 400D in FIG. 4D). The first circuit region, e.g., the ECO cell 400A, and the second circuit region, e.g., the ECO cell 400B, have identical active regions OD1, OD2, identical gate regions 410-418, and identical MD contact structures 420-427, 430-437. Each of the first and second circuit regions comprises a corresponding set of transistors including transistors P1-P5 and N1-N5.

At operation 545, depositing and patterning processes are performed to obtain various via structures and conductive patterns. Specifically, first and second sets of via structures are formed correspondingly over the gate regions and the contact structures correspondingly in the first and second circuit regions. In a metal layer, first and second sets of conductive patterns are formed correspondingly over the first and second sets of via structures. The first set of via structures and the first set of conductive patterns electrically couple the first set of transistors into no functional circuit, while leaving no floating source/drain in the first set of transistors. The second set of via structures and the second set of conductive patterns electrically couple at least some transistors in the second set of transistors into a functional circuit.

For example, as described with respect to FIG. 4A, the first circuit region, e.g., the ECO cell 400A, comprises a first set of VD vias 451, 453, 454, 455, 457, 461, 462, 463, 464, 465, 466, 467 and VG vias 471, 473, 474, 476, 477, and a first set of M0 conductors 481, 482, 483, 484 which couple the first set of transistors P1-P5, N1-N5 of the ECO cell 400A into no functional circuit. As also described with respect to FIG. 4A, there is no floating source/drain in the first set of transistors P1-P5, N1-N5 of the ECO cell 400A. As a result, it is possible in one or more embodiments to avoid issues and/or forbidden dummy devices associated with floating source/drains.

As described with respect to FIG. 4B, the second circuit region, e.g., the ECO cell 400B, comprises a second set of VD vias 451B, 453, 454, 455, 457, 461, 462, 463, 464, 465B, 466, 467 and VG vias 471B, 473B, 474B, 476B, 477B, and a second set of M0 conductors 481B, 482B, 483B, 484B which couple transistors P5, N5 in the second set of transistors P1-P5, N1-N5 of the ECO cell 400B into a functional circuit, e.g., an inverter. The remaining transistors P1-P4, N1-N4 in the second set of transistors of the ECO cell 400B are also free of floating source/drains to avoid issues and/or forbidden dummy devices associated with floating source/drains. In at least one embodiment, one or more advantages described herein are achievable by an IC device manufactured in accordance with the method 500C.

The described methods include example operations, but they are not necessarily required to be performed in the order shown. Operations may be added, replaced, changed order, and/or eliminated as appropriate, in accordance with the spirit and scope of embodiments of the disclosure. Embodiments that combine different features and/or different embodiments are within the scope of the disclosure and will be apparent to those of ordinary skill in the art after reviewing this disclosure.

In some embodiments, at least one method(s) discussed above is performed in whole or in part by at least one EDA system. In some embodiments, an EDA system is usable as part of a design house of an IC manufacturing system discussed below.

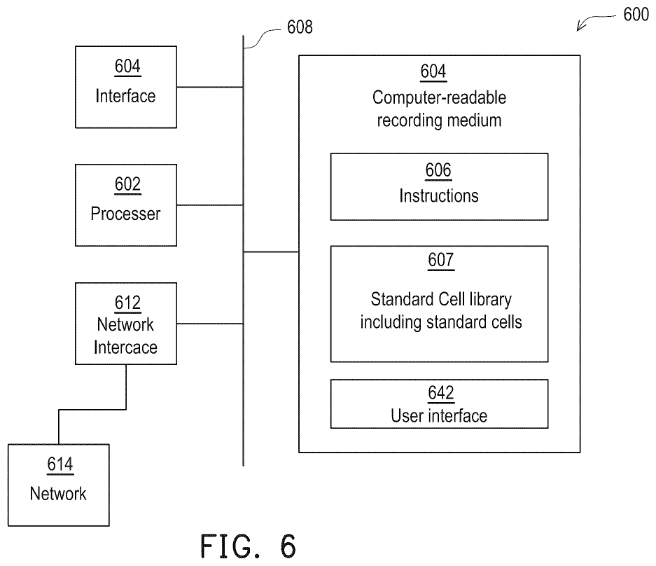

FIG. 6 is a block diagram of an electronic design automation (EDA) system 600 in accordance with some embodiments.

In some embodiments, EDA system 600 includes an APR system. Methods described herein of designing layouts represent wire routing arrangements, in accordance with one or more embodiments, are implementable, for example, using EDA system 600, in accordance with some embodiments.

In some embodiments, EDA system 600 is a general purpose computing device including a hardware processor 602 and a non-transitory, computer-readable recording medium 604. Recording medium 604, amongst other things, is encoded with, i.e., stores, computer program code 606, i.e., a set of executable instructions. Execution of instructions 606 by hardware processor 602 represents (at least in part) an EDA tool which implements a portion or all of the methods described herein in accordance with one or more embodiments (hereinafter, the noted processes and/or methods).

Processor 602 is electrically coupled to computer-readable recording medium 604 via a bus 608. Processor 602 is also electrically coupled to an I/O interface 610 by bus 608. A network interface 612 is also electrically connected to processor 602 via bus 608. Network interface 612 is connected to a network 614, so that processor 602 and computer-readable recording medium 604 are capable of connecting to external elements via network 614. Processor 602 is configured to execute computer program code 606 encoded in computer-readable recording medium 604 in order to cause system 600 to be usable for performing a portion or all of the noted processes and/or methods. In one or more embodiments, processor 602 is a central processing unit (CPU), a multi-processor, a distributed processing system, an application specific integrated circuit (ASIC), and/or a suitable processing unit.

In one or more embodiments, computer-readable recording medium 604 is an electronic, magnetic, optical, electromagnetic, infrared, and/or a semiconductor system (or apparatus or device). For example, computer-readable recording medium 604 includes a semiconductor or solid-state memory, a magnetic tape, a removable computer diskette, a random access memory (RAM), a read-only memory (ROM), a rigid magnetic disk, and/or an optical disk. In one or more embodiments using optical disks, computer-readable recording medium 604 includes a compact disk-read only memory (CD-ROM), a compact disk-read/write (CD-R/W), and/or a digital video disc (DVD).

In one or more embodiments, recording medium 604 stores computer program code 606 configured to cause system 600 (where such execution represents (at least in part) the EDA tool) to be usable for performing a portion or all of the noted processes and/or methods. In one or more embodiments, recording medium 604 also stores information which facilitates performing a portion or all of the noted processes and/or methods. In one or more embodiments, recording medium 604 stores library 607 of standard cells including such standard cells as disclosed herein.

EDA system 600 includes I/O interface 610. I/O interface 610 is coupled to external circuitry. In one or more embodiments, I/O interface 610 includes a keyboard, keypad, mouse, trackball, trackpad, touchscreen, and/or cursor direction keys for communicating information and commands to processor 602.

EDA system 600 also includes network interface 612 coupled to processor 602. Network interface 612 allows system 600 to communicate with network 614, to which one or more other computer systems are connected. Network interface 612 includes wireless network interfaces such as BLUETOOTH, WIFI, WIMAX, GPRS, or WCDMA; or wired network interfaces such as ETHERNET, USB, or IEEE-1364. In one or more embodiments, a portion or all of noted processes and/or methods, is implemented in two or more systems 600.

System 600 is configured to receive information through I/O interface 610. The information received through I/O interface 610 includes one or more of instructions, data, design rules, libraries of standard cells, and/or other parameters for processing by processor 602. The information is transferred to processor 602 via bus 608. EDA system 600 is configured to receive information related to a user interface (UI) through I/O interface 610. The information is stored in computer-readable recording medium 604 as UI 642.

In some embodiments, a portion or all of the noted processes and/or methods is implemented as a standalone software application for execution by a processor. In some embodiments, a portion or all of the noted processes and/or methods is implemented as a software application that is a part of an additional software application. In some embodiments, a portion or all of the noted processes and/or methods is implemented as a plug-in to a software application. In some embodiments, at least one of the noted processes and/or methods is implemented as a software application that is a portion of an EDA tool. In some embodiments, a portion or all of the noted processes and/or methods is implemented as a software application that is used by EDA system 600. In some embodiments, a layout which includes standard cells is generated using a tool such as VIRTUOSO® available from CADENCE DESIGN SYSTEMS, Inc., or another suitable layout generating tool.

In some embodiments, the processes are realized as functions of a program stored in a non-transitory computer readable recording medium. Examples of a non-transitory computer readable recording medium include, but are not limited to, external/removable and/or internal/built-in storage or memory unit, e.g., one or more of an optical disk, such as a DVD, a magnetic disk, such as a hard disk, a semiconductor memory, such as a ROM, a RAM, a memory card, and the like.

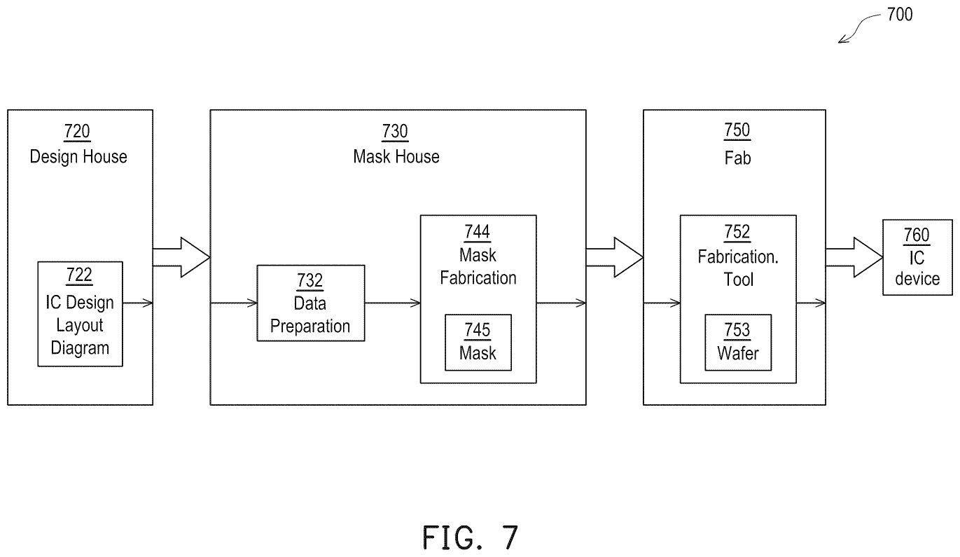

FIG. 7 is a block diagram of an integrated circuit (IC) manufacturing system 700, and an IC manufacturing flow associated therewith, in accordance with some embodiments. In some embodiments, based on a layout, at least one of (A) one or more semiconductor masks or (B) at least one component in a layer of a semiconductor integrated circuit is fabricated using manufacturing system 700.

In FIG. 7, IC manufacturing system 700 includes entities, such as a design house 720, a mask house 730, and an IC manufacturer/fabricator (“fab”) 750, that interact with one another in the design, development, and manufacturing cycles and/or services related to manufacturing an IC device 760. The entities in system 700 are connected by a communications network. In some embodiments, the communications network is a single network. In some embodiments, the communications network is a variety of different networks, such as an intranet and the Internet. The communications network includes wired and/or wireless communication channels. Each entity interacts with one or more of the other entities and provides services to and/or receives services from one or more of the other entities. In some embodiments, two or more of design house 720, mask house 730, and IC fab 750 is owned by a single larger company. In some embodiments, two or more of design house 720, mask house 730, and IC fab 750 coexist in a common facility and use common resources.

Design house (or design team) 720 generates an IC design layout 722. IC design layout 722 includes various geometrical patterns designed for an IC device 760. The geometrical patterns correspond to patterns of metal, oxide, or semiconductor layers that make up the various components of IC device 760 to be fabricated. The various layers combine to form various IC features. For example, a portion of IC design layout 722 includes various IC features, such as an active region, gate electrode, source and drain, metal lines or vias of an interlayer interconnection, and openings for bonding pads, to be formed in a semiconductor substrate (such as a silicon wafer) and various material layers disposed on the semiconductor substrate. Design house 720 implements a proper design procedure to form IC design layout 722. The design procedure includes one or more of logic design, physical design or place-and-route operation. IC design layout 722 is presented in one or more data files having information of the geometrical patterns. For example, IC design layout 722 can be expressed in a GDSII file format or DFII file format.

Mask house 730 includes data preparation 732 and mask fabrication 744. Mask house 730 uses IC design layout 722 to manufacture one or more masks 745 to be used for fabricating the various layers of IC device 760 according to IC design layout 722. Mask house 730 performs mask data preparation 732, where IC design layout 722 is translated into a representative data file (“RDF”). Mask data preparation 732 provides the RDF to mask fabrication 744. Mask fabrication 744 includes a mask writer. A mask writer converts the RDF to an image on a substrate, such as a mask (reticle) 745 or a semiconductor wafer 753. The design layout 722 is manipulated by mask data preparation 732 to comply with particular characteristics of the mask writer and/or requirements of IC fab 750. In FIG. 7, mask data preparation 732 and mask fabrication 744 are illustrated as separate elements. In some embodiments, mask data preparation 732 and mask fabrication 744 can be collectively referred to as mask data preparation.

In some embodiments, mask data preparation 732 includes optical proximity correction (OPC) which uses lithography enhancement techniques to compensate for image errors, such as those that can arise from diffraction, interference, other process effects and the like. OPC adjusts IC design layout 722. In some embodiments, mask data preparation 732 includes further resolution enhancement techniques (RET), such as off axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, mask data preparation 732 includes a mask rule checker (MRC) that checks the IC design layout 722 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the IC design layout 722 to compensate for limitations during mask fabrication 744, which may undo part of the modifications performed by OPC in order to meet mask creation rules.

In some embodiments, mask data preparation 732 includes lithography process checking (LPC) that simulates processing that will be implemented by IC fab 750 to fabricate IC device 760. LPC simulates this processing based on IC design layout 722 to create a simulated manufactured device, such as IC device 760. The processing parameters in LPC simulation can include parameters associated with various processes of the IC manufacturing cycle, parameters associated with tools used for manufacturing the IC, and/or other aspects of the manufacturing process. LPC takes into account various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine IC design layout 722.

It should be understood that the above description of mask data preparation 732 has been simplified for the purposes of clarity. In some embodiments, data preparation 732 includes additional features such as a logic operation (LOP) to modify the IC design layout 722 according to manufacturing rules. Additionally, the processes applied to IC design layout 722 during data preparation 732 may be executed in a variety of different orders.

After mask data preparation 732 and during mask fabrication 744, a mask 745 or a group of masks 745 are fabricated based on the modified IC design layout 722. In some embodiments, mask fabrication 744 includes performing one or more lithographic exposures based on IC design layout 722. In some embodiments, an electron-beam (e-beam) or a mechanism of multiple e-beams is used to form a pattern on a mask (photomask or reticle) 745 based on the modified IC design layout 722. Mask 745 can be formed in various technologies. In some embodiments, mask 745 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region and transmits through the transparent regions. In one example, a binary mask version of mask 745 includes a transparent substrate (e.g., fused quartz) and an opaque material (e.g., chromium) coated in the opaque regions of the binary mask. In another example, mask 745 is formed using a phase shift technology. In a phase shift mask (PSM) version of mask 745, various features in the pattern formed on the phase shift mask are configured to have proper phase difference to enhance the resolution and imaging quality. In various examples, the phase shift mask can be attenuated PSM or alternating PSM. The mask(s) generated by mask fabrication 744 is used in a variety of processes. For example, such a mask(s) is used in an ion implantation process to form various doped regions in semiconductor wafer 753, in an etching process to form various etching regions in semiconductor wafer 753, and/or in other suitable processes.

IC fab 750 is an IC fabrication business that includes one or more manufacturing facilities for the fabrication of a variety of different IC products. In some embodiments, IC Fab 750 is a semiconductor foundry. For example, there may be a manufacturing facility for the front end fabrication of a plurality of IC products (front-end-of-line (FEOL) fabrication), while a second manufacturing facility may provide the back end fabrication for the interconnection and packaging of the IC products (back-end-of-line (BEOL) fabrication), and a third manufacturing facility may provide other services for the foundry business.

IC fab 750 includes fabrication tools 752 configured to execute various manufacturing operations on semiconductor wafer 753 such that IC device 760 is fabricated in accordance with the mask(s), e.g., mask 745. In various embodiments, fabrication tools 752 include one or more of a wafer stepper, an ion implanter, a photoresist coater, a process chamber, e.g., a CVD chamber or LPCVD furnace, a CMP system, a plasma etch system, a wafer cleaning system, or other manufacturing equipment capable of performing one or more suitable manufacturing processes as discussed herein.

IC fab 750 uses mask(s) 745 fabricated by mask house 730 to fabricate IC device 760. Thus, IC fab 750 at least indirectly uses IC design layout 722 to fabricate IC device 760. In some embodiments, semiconductor wafer 753 is fabricated by IC fab 750 using mask(s) 745 to form IC device 760. In some embodiments, the IC fabrication includes performing one or more lithographic exposures based at least indirectly on IC design layout 722. Semiconductor wafer 753 includes a silicon substrate or other proper substrate having material layers formed thereon. Semiconductor wafer 753 further includes one or more of various doped regions, dielectric features, multilevel interconnects, and the like (formed at subsequent manufacturing steps).

In some embodiments, an integrated circuit (IC) device comprises a first transistor, and a second transistor. The first transistor comprises a first terminal configured to receive a first power supply voltage, a second terminal, and a gate terminal. The gate terminal is configured to receive a second power supply voltage different from the first power supply voltage, or a first voltage corresponding to the first power supply voltage, or a second voltage corresponding to the second power supply voltage. The second transistor comprises two terminals electrically coupled to the second terminal of the first transistor.

In some embodiments, an integrated circuit (IC) device comprises a first active region of a first conductivity type, a second active region of a second conductivity type different from the first conductivity type, and a plurality of gate regions extending continuously across the first active region and the second active region. The plurality of gate regions and the first active region correspondingly configure a plurality of transistors of a first type. The plurality of gate regions and the second active region correspondingly configure a plurality of transistors of a second type different from the first type. The plurality of transistors of the first type comprises a first transistor having a first source/drain electrically coupled to a first power rail configured to carry a first power supply voltage, and a second source/drain. The plurality of transistors of the first type further comprises a second transistor having a first source/drain and a second source/drain both electrically coupled to the second source/drain of the first transistor. The plurality of transistors of the second type comprises a third transistor having a first source/drain electrically coupled to a second power rail configured to carry a second power supply voltage different from the first power supply voltage, and a second source/drain. The plurality of transistors of the second type further comprises a fourth transistor having both first and second source/drains electrically coupled to the second source/drain of the third transistor.

In some embodiments, a method comprises forming, over a substrate, a first circuit region and a second circuit region. Each of the first circuit region and the second circuit region comprises active regions having different conductivity types, and gate regions and contact structures arranged alternatingly and extending across the active regions. The active regions, the gate regions and the contact structures in the first circuit region are correspondingly identical to the active regions, the gate regions and the contact structures in the second circuit region. The active regions and the gate regions in the first circuit region configure a first set of transistors. The active regions and the gate regions in the second circuit region configure a second set of transistors. The method further comprises depositing and patterning a first set of via structures over the gate regions and the contact structures in the first circuit region, a second set of via structures over the gate regions and the contact structures in the second circuit region, and, in a metal layer, a first set of conductive patterns over the first set of via structures and a second set of conductive patterns over the second set of via structures. The first set of via structures and the first set of conductive patterns electrically couple the first set of transistors into no functional circuit, while leaving no floating source/drain in the first set of transistors. The second set of via structures and the second set of conductive patterns electrically couple at least some transistors in the second set of transistors into a functional circuit.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) device, comprising:
a first transistor comprising:
a first terminal configured to receive a first power supply voltage,
a second terminal, and
a gate terminal configured to receive
a second power supply voltage different from the first power supply voltage, or
a first voltage corresponding to the first power supply voltage, or
a second voltage corresponding to the second power supply voltage; and
a second transistor comprising two terminals electrically coupled to the second terminal of the first transistor.

2. The IC device of claim 1, wherein
the first voltage is different from the first power supply voltage by a voltage drop across the first transistor in a turned ON state.

3. The IC device of claim 1, wherein
the first voltage is variable between the first power supply voltage and a threshold voltage of the first transistor.

4. The IC device of claim 1, wherein
the two terminals of the second transistor that are electrically coupled to the second terminal of the first transistor comprise a first terminal and a gate terminal of the second transistor, and
the second transistor further comprises a second terminal configured to receive the first power supply voltage.

5. The IC device of claim 1, wherein
the two terminals of the second transistor that are electrically coupled to the second terminal of the first transistor comprise a first terminal and a second terminal of the second transistor, and
the second transistor further comprises a gate terminal configured to receive the second voltage.

6. The IC device of claim 1, further comprising:
a third transistor of a conductivity type different from that of the first transistor, the third transistor comprising:
a first terminal configured to receive the second power supply voltage,
a second terminal, and
a gate terminal configured to receive the first voltage or the second voltage; and
a fourth transistor comprising at least two terminals electrically coupled to the second terminal of the third transistor.

7. The IC device of claim 6, wherein
the second voltage is different from the second power supply voltage by a voltage drop across the third transistor in a turned ON state.

8. The IC device of claim 6, wherein
the second voltage is variable between the second power supply voltage and a threshold voltage of the third transistor.

9. The IC device of claim 6, wherein
the at least two terminals of the fourth transistor that are electrically coupled to the second terminal of the third transistor comprise a first terminal and a second terminal of the fourth transistor, and
the fourth transistor further comprises a gate terminal configured to receive the second power supply voltage.

10. The IC device of claim 6, wherein
the at least two terminals of the fourth transistor that are electrically coupled to the second terminal of the third transistor comprise a first terminal, a second terminal and a gate terminal of the fourth transistor.

11. An integrated circuit (IC) device, comprising:
a first active region of a first conductivity type;
a second active region of a second conductivity type different from the first conductivity type; and
a plurality of gate regions extending continuously across the first active region and the second active region,
wherein
the plurality of gate regions and the first active region correspondingly configure a plurality of transistors of a first type,
the plurality of gate regions and the second active region correspondingly configure a plurality of transistors of a second type different from the first type,
the plurality of transistors of the first type comprises:
a first transistor having a first source/drain electrically coupled to a first power rail configured to carry a first power supply voltage, and a second source/drain, and
a second transistor having a first source/drain and a second source/drain both electrically coupled to the second source/drain of the first transistor, and
the plurality of transistors of the second type comprises:
a third transistor having a first source/drain electrically coupled to a second power rail configured to carry a second power supply voltage different from the first power supply voltage, and a second source/drain, and
a fourth transistor having both first and second source/drains electrically coupled to the second source/drain of the third transistor.

12. The IC device of claim 11, wherein at least one of
a gate of the first transistor and a gate of the third transistor are configured by a same gate region among the plurality of gate regions,
a gate of the second transistor and a gate of the fourth transistor are configured by a same gate region among the plurality of gate regions, or
the gate of the first transistor and the gate of the fourth transistor are configured by a same gate region among the plurality of gate regions.

13. The IC device of claim 11, wherein
the plurality of transistors of the first type further comprises a fifth transistor having
a first source/drain electrically coupled to the first power rail,
a second source/drain, and
a gate electrically coupled to the second power rail, and
a gate of the first transistor is electrically coupled to
the second power rail,
the second source/drain of the third transistor, or
the second source/drain of the fifth transistor.

14. The IC device of claim 13, wherein
the plurality of transistors of the second type further comprises a sixth transistor having
a first source/drain and a second source/drain electrically coupled to the second power rail, and
a gate electrically coupled to the second source/drain of the third transistor.

15. The IC device of claim 14, further comprising:
a first metal layer over the plurality of gate regions, the first metal layer comprising:
a first conductive pattern electrically coupling the second source/drain of the first transistor to the first source/drain and the second source/drain of the second transistor,
a second conductive pattern electrically coupling the second source/drain of the fifth transistor to the gate of the first transistor,
a third conductive pattern electrically coupling the first source/drain and the second source/drain of the sixth transistor to the gate of the fifth transistor, and
a fourth conductive pattern electrically coupling the second source/drain of the third transistor to the first source/drain and the second source/drain of the fourth transistor.

16. The IC device of claim 11, wherein
at least one of a gate of the first transistor and a gate of the second transistor is electrically coupled to the second source/drain of the third transistor.

17. The IC device of claim 11, wherein
gates of the first through fourth transistors are electrically coupled to the second source/drain of the third transistor.

18. The IC device of claim 11, further comprising:
a first metal layer over the plurality of gate regions, the first metal layer comprising:
a first conductive pattern electrically coupling the second source/drain of the first transistor to the first source/drain and the second source/drain of the second transistor,
a second conductive pattern electrically coupling a gate of the first transistor to a gate of the second transistor, and
a third conductive pattern electrically coupling the second source/drain of the third transistor to the first source/drain and the second source/drain of the fourth transistor; and
a second metal layer over the first metal layer, the second metal layer comprising:
a fourth conductive pattern electrically coupling the second conductive pattern to the third conductive pattern.

19. A method, comprising:
forming, over a substrate, a first circuit region and a second circuit region, wherein
each of the first circuit region and the second circuit region comprises active regions having different conductivity types, and gate regions and contact structures arranged alternatingly and extending across the active regions,
the active regions, the gate regions and the contact structures in the first circuit region are correspondingly identical to the active regions, the gate regions and the contact structures in the second circuit region,
the active regions and the gate regions in the first circuit region configure a first set of transistors, and
the active regions and the gate regions in the second circuit region configure a second set of transistors; and
depositing and patterning
a first set of via structures over the gate regions and the contact structures in the first circuit region,
a second set of via structures over the gate regions and the contact structures in the second circuit region, and
in a metal layer, a first set of conductive patterns over the first set of via structures, and a second set of conductive patterns over the second set of via structures,
wherein
the first set of via structures and the first set of conductive patterns electrically couple the first set of transistors into no functional circuit, while leaving no floating source/drain in the first set of transistors, and
the second set of via structures and the second set of conductive patterns electrically couple at least some transistors in the second set of transistors into a functional circuit.

20. The method of claim 19, wherein
the second set of via structures and the second set of conductive patterns electrically couple remaining transistors in the second set of transistors into no functional circuit, while leaving no floating source/drain among the remaining transistors.
